(19) United States
(12) Patent Application Publication
(10) Pub. No.: US 2024/0370608 A1
(43) Pub. Date: Nov. 7, 2024

(54) ARTIFICIAL INTELLIGENCE-SIMULATION BASED SCIENCE

(71) Applicant: Pasteur Labs, Inc., Brooklyn, NY (US)

(72) Inventor: Alexander Lavin, Brooklyn, NY (US)

(21) Appl. No.: 18/664,623

(22) Filed: May 15, 2024

Related U.S. Application Data
(63) Continuation of application No. PCT/US2022/080174, filed on Nov. 18, 2022.
(60) Provisional application No. 63/281,192, filed on Nov. 19, 2021.

(51) Int. Cl. G06F 30/20

(52) U.S. Cl. CPC G06F 30/20

(57) ABSTRACT

Described herein are technologies, integrations, and workflows to allow for a unified, holistic perspective in order to advance the intersection of AI and simulation sciences. These technologies, integrations, and workflows may catalyze synergistic AI and simulation to advance the fields of science and intelligence through AI-enabled simulation.

### CROSS REFERENCE TO RELATED APPLICATIONS

This application is a continuation application of International Patent Application No. PCT/US2022/080174, filed Nov. 18, 2022, which application claims the benefit of U.S. Provisional Application No. 63/281,192, filed Nov. 19, 2021, each of which is hereby incorporated by reference herein in its entirety.

### BACKGROUND

Simulation has become an indispensable tool for researchers across the sciences to explore the behavior of complex, dynamic systems under varying conditions. However, the utility of a simulation can be limited in several ways. For example, computational cost may limit the level of geometric details, complexity of physics, and the number of simulator runs, despite advances in hardware. The utility of simulations can also be limited in that simulators can be biased and can rarely integrate with real-world data streams. Simulation codes can also be composed of low-level mechanistic components that may be non-differentiable and may lead to intractable likelihoods. Further, sensitivity and uncertainty analyses can be impractical for expensive simulators, and simplifying assumptions often render the results of a simulation unusable for hypothesis testing and practical decision-making.

Recent progress with artificial intelligence (AI) and machine learning (ML) in the sciences has advanced simulation methods towards several key objectives in order to make AI/ML useful in sciences. These include importing domain knowledge into models, exporting knowledge from learned models, leveraging ML for intractable problems to be data-efficient, quantifying and reasoning about uncertainties in models and data, maximizing utility of real-world data, generating myriads of synthetic data, and inferring causal relationships in datasets. However, this is a nascent and disparate area, and a unifying, holistic perspective may advance the intersection of AI and simulation sciences.

### SUMMARY

Traditional scientific methods may provide useful step-by-step guides for knowledge gathering and may have fundamentally shaped how humans think about the exploration of nature and scientific discovery. However, these guides may have hindered necessary paradigm shifts by being slow and/or subjective (e.g., since scientific discovery can be driven by the scientist's ingenuity as well as bias). Scientific experimentation and discovery in many domains can expect significant strides through the intersection of AI and simulation sciences, which may enable necessary paradigm shifts. The present disclosure addresses the above by providing the essential technologies, integrations, and workflows to allow for a unified, holistic perspective in order to advance the intersection of AI and simulation sciences. The essential technologies, integrations, and workflows can catalyze synergistic AI and simulation to broadly advance the fields of science and intelligence by targeting AI-enabled simulation, in contrast to the common use of simulation to train AI agents or ML models (e.g., in game environments).

The present disclosure comprises anew territory of computational engines and methods and unifies multiple computing perspectives and interdisciplinary sciences. This new field can be defined as Simulation Intelligence (SI), which can merge scientific computing, scientific simulation, and artificial intelligence in order to study processes and systems in silico to better understand and discover in situ phenomena (e.g., in silico testbeds for developing, experimenting, and testing AI/ML prior to in situ use). In some cases, SI can study complex, dynamic systems and processes in silico by incorporating multiple scales, multiple physics, multi-agent scenarios, mechanistic and data-driven models in rich environments, which can be used to understand and discover in situ causal, complex, collective, emergent, and open-ended phenomena. SI can inform real-world systems and users in keyways, such as causal discovery, counterfactual reasoning and decision-making, human-machine teaming, online/dynamic optimization, uncertainty quantification and propagation, optimal design and inverse problem solving, and AI/ML testing, verification and validation.

The present disclosure details various designs, implementations, applications, and extensions of a Simulation Intelligence Operating system (SIOS). SIOS may provide novel scientific workflows, which has the potential to expand the space of science and intelligence beyond what is feasible with current technologies and humans in the standard scientific method. This SIOS may be integrated into a Simulation Intelligence (SI) stack, which may be used to broaden the scientific method and may provide an essential step towards the Nobel Turing Challenge, creating a machine intelligence engine for scientific discovery. The SIOS may also be referred to as a simulation-artificial intelligence (Sim-AI) operating system (OS) which are used interchangeably throughout the specification.

In one aspect disclosed herein are systems comprising: a simulation module layer that is configured to be integrated and used in a simulation-artificial intelligence (Sim-AI) operating system (OS), wherein the simulation module layer comprises one or more domain-specific computing modules that are useable for simulation intelligence of one or more target applications. In some embodiments, the simulation intelligence of the one or more target applications may comprise a AI-enabled simulation of the one or more target applications. In some embodiments, the one or more domain-specific computing modules are configured or customized for one or more of the following: simulation-based inferences, multi-physics and multi-scale effects, surrogate modeling and emulation, semi-mechanistic modeling, probabilistic domain-specific language (DSL) simulation, open-endedness capabilities, agent-based modeling, or causal machine learning (ML). In some embodiments, simulation-based inference comprises likelihood-free inference. In some embodiments, multi-physics and multi-scale effects comprise modeling, learning, inference, or a combination thereof. In some embodiments, the one or more target applications comprise one or more of the following: parallel computing for interdisciplinary physics, multi-physics multi-scale simulation, simulators as computation graphs for causal reasoning, or uncertainty quantification and reasoning. In some embodiments, the interdisciplinary physics, multi-physics multi-scale simulation may comprise simulation of complex environments with one or more coupled spatiotemporal processes (e.g., climate science and geoengineering, nuclear energy and engineering, systems biology, computational chemistry and materials science, etc.). In some embodiments, the simulation module layer is provided over one or more programming engines within the Sim-AI OS. In some cases, the one or more programming engines comprise at least one of a probabilistic programming engine or a differentiable programming engine. In some embodiments, the simulation module layer is configured to be operably coupled to a hardware module layer in a configuration that is optimized for machine code execution. In some cases, the configuration is optimized for machine code execution using at least one or more of the following: (i) domain-specific languages (DSL), (ii) hardware-software design automation, or (iii) machine intentional programming. In some cases, the hardware module layer comprises a flexible hardware system that is operably coupled to a differentiable programming engine, a probabilistic programming engine, or a combination thereof in the Sim-AI OS. In some cases, the hardware module layer comprises a high performance computing (HPC) system that is operably coupled to a probabilistic programming engine, a differentiable programming engine, or a combination thereof in the Sim-AI OS. In some instances, the flexible hardware system is operably coupled to the differentiable programming engine, the probabilistic programming engine, or the combination thereof via a machine programming module. In some instances, the machine programming module is configured for intentional programming comprising an automated process of generating machine-optimized programs directly from a user's instructions or high-level intent. In some instances, the machine programming module is configured to serve as a layer of abstraction between the hardware module layer and the simulation module layer. In some embodiments, the one or more domain-specific computing modules comprise at least one expert knowledge model that is synergistically combined or fused with at least one data-driven surrogate model. In some embodiments, the at least one expert knowledge model comprises one or more differential equations, a semi-parametric model, or a non-parametric model. In some embodiments, the simulation module layer is configured to simulate and learn processes and systems spanning multiple physics processes and/or multiple spatial-temporal scales. In some embodiments, the system may further comprise: encoding domain expertise and causal structure into the simulation module layer. In some embodiments, encoding domain expertise and causal structure into the simulation module layer may be in the form of one or more graphical models. In some embodiments, the one or more graphical models may comprise no mechanistic and/or data driven components. In some embodiments, the one or more graphical models may comprise one or more mechanistic and/or data driven components. In some embodiments, encoding domain expertise and causal structure into the simulation module layer may be in the form of a structure that is represented as a computation graph. In some embodiments, the computation graph may be a same computation graph as other modules or components (e.g., machine learning components). In some embodiments, the computational graph can be exposed for both higher level user intent and lower level machine or hardware programming. In some embodiments, the simulation module layer is configured to generate one or more counterfactual simulations that simulate possible future predictions over one or more time scales and high-dimensional/multimodal data. In some embodiments, the one or more counterfactual simulations are grounded in the mathematics of causality as a result of a causal graph or one or more confounders. In some embodiments, the one or more counterfactual simulations can be grounded in the mathematics of causality as a result of a causal graph (e.g., a causal graph computational architecture), which may allow for cause-effect queries and interventions. In some embodiments, the one or more counterfactual simulations can be grounded in the mathematics of causality as a result of one or more confounders (e.g., a known confounder or a hidden confounder). In some embodiments, the simulation module layer is capable of running a legacy simulation codebase. In some embodiments, the simulation module layer is capable of running a legacy simulation codebase comprising a probabilistic programming engine. In some embodiments, the simulation module layer, the workflow layer, or a combination thereof is capable of being scaled, integrated, compiled, accelerated, or a combination thereof without refactoring or rewriting legacy codebases. In some embodiments, the simulation module layer, the workflow layer, or a combination thereof is configured to receive and integrate real-world datasets and online data streams comprising of structured and unstructured data. In some embodiments, the simulation module layer is configured to update simulations in an online fashion with incoming data. In some embodiments, the simulation module layer is configured to be operably coupled to one or more workflow layers. In some cases, the workflow layer comprises a closed-loop, inverse design automated process in silico that is designed to maximize search efficiency and minimize in situ resource utilization. In some embodiments, the system may further comprise: implementing one or more workflow pipelines that traverse between two or more of any of the layers and information paths associated thereof.

In another aspect, disclosed herein are methods comprising: providing a simulation module layer that is configured to be integrated and used in a simulation-artificial intelligence (Sim-AI) operating system (OS), wherein the simulation module layer comprises one or more domain-specific computing modules; and using the one or more domain-specific computing modules for simulation intelligence of one or more target applications. In some embodiments, the simulation intelligence of the one or more target applications may comprise a AI-enabled simulation of the one or more target applications. In some embodiments, the one or more domain-specific computing modules are configured or customized for one or more of the following: simulation-based inference, multi-physics and multi-scale effects, surrogate modeling and emulation, semi-mechanistic modeling, probabilistic domain-specific language (DSL) simulation, open-endedness capabilities, agent-based modeling, or causal machine learning (ML). In some embodiments, simulation-based inference comprises likelihood-free inference. In some embodiments, multi-physics and multi-scale effects comprise modeling, learning, inference, or a combination thereof. In some embodiments, the one or more target applications comprise one or more of the following: parallel computing for interdisciplinary physics, multi-physics multi-scale simulation, simulators as computation graphs for causal reasoning, or uncertainty quantification and reasoning. In some embodiments, the interdisciplinary physics, multi-physics multi-scale simulation may comprise simulation of complex environments with one or more coupled spatiotemporal processes (e.g., climate science and geoengineering, nuclear energy and engineering, systems biology, computational chemistry and materials science, etc.). In some embodiments, the simulation module layer is provided over one or more programming engines within the Sim-AI OS. In some cases, the one or more programming engines comprise at least one of a probabilistic programming engine or a differentiable programming engine. In some embodiments, the simulation module layer is configured to be operably coupled to a hardware module layer in a configuration that is optimized for machine code execution. In some cases, the configuration is optimized for machine code execution using at least one or more of the following: (i) domain-specific languages (DSL), (ii) hardware-software design automation, or (iii) machine intentional programming. In some cases, the hardware module layer comprises a flexible hardware system that is operably coupled to a differentiable programming engine, a probabilistic programming engine, or a combination thereof in the Sim-AI OS. In some cases, the hardware module layer comprises a high performance computing (HPC) system that is operably coupled to a probabilistic programming engine, a differentiable programming engine, or a combination thereof in the Sim-AI OS. In some instances, the flexible hardware system is operably coupled to the differentiable programming engine, the probabilistic programming engine, or the combination thereof via a machine programming module. In some instances, the machine programming module is configured for intentional programming comprising an automated process of generating machine-optimized programs directly from a user's instructions or high-level intent. In some instances, the machine programming module is configured to serve as a layer of abstraction between the hardware module layer and the simulation module layer. In some embodiments, the one or more domain-specific computing modules comprise at least one expert knowledge model that is synergistically combined or fused with at least one data-driven surrogate model. In some embodiments, the at least one expert knowledge model comprises one or more differential equations, a semi-parametric model, or a non-parametric model. In some embodiments, the simulation module layer is configured to simulate and learn processes and systems spanning multiple physics processes and/or multiple spatial-temporal scales. In some embodiments, the system may further comprise: encoding domain expertise and causal structure into the simulation module layer. In some embodiments, encoding domain expertise and causal structure into the simulation module layer may be in the form of one or more graphical models. In some embodiments, the one or more graphical models may comprise no mechanistic and/or data driven components. In some embodiments, the one or more graphical models may comprise one or more mechanistic and/or data driven components. In some embodiments, encoding domain expertise and causal structure into the simulation module layer may be in the form of a structure that is represented as a computation graph. In some embodiments, the computation graph may be a same computation graph as other modules or components (e.g., machine learning components). In some embodiments, the computational graph can be exposed for both higher level user intent and lower level machine or hardware programming. In some embodiments, the simulation module layer is configured to generate one or more counterfactual simulations that simulate possible future predictions over one or more time scales and high-dimensional/multimodal data. In some embodiments, the one or more counterfactual simulations are grounded in the mathematics of causality as a result of a causal graph or one or more confounders. In some embodiments, the one or more counterfactual simulations can be grounded in the mathematics of causality as a result of a causal graph (e.g., a causal graph computational architecture), which may allow for cause-effect queries and interventions. In some embodiments, the one or more counterfactual simulations can be grounded in the mathematics of causality as a result of one or more confounders (e.g., a known confounder or a hidden confounder). In some embodiments, the simulation module layer is capable of running a legacy simulation codebase. In some embodiments, the simulation module layer is capable of running a legacy simulation codebase comprising a probabilistic programming engine. In some embodiments, the simulation module layer, the workflow layer, or a combination thereof is capable of being scaled, integrated, compiled, accelerated, or a combination thereof without refactoring or rewriting legacy codebases. In some embodiments, the simulation module layer is configured to receive and integrate real-world datasets and online data streams comprising of structured and unstructured data. In some embodiments, the simulation module layer is configured to update simulations in an online fashion with incoming data. In some embodiments, the simulation module layer is configured to be operably coupled to one or more workflow layers. In some cases, the one or more workflow layers comprises a closed-loop, inverse design automated process in silico that is designed to maximize search efficiency and minimize in situ resource utilization. In some embodiments, the system may further comprise: implementing one or more workflow pipelines that traverse between two or more of any of the layers and information paths associated thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

A better understanding of the features and advantages of the present subject matter will be obtained by reference to the following detailed description that sets forth illustrative embodiments and the accompanying drawings of which:

FIG. 1 shows anon-limiting example of a block diagram for a system comprising a Sim-AI OS;

FIG. 2 shows anon-limiting example of a block diagram of a Sim-AI OS;

FIG. 3 shows anon-limiting example of a block diagram of modules in a Sim-AI OS;

FIG. 4 shows anon-limiting example of a block diagram of an interaction between modules and workflows;

FIG. 5 shows anon-limiting example of block diagram for inferring hidden states or parameters from observations or measurements;

FIG. 6 shows anon-limiting example of block diagram for discovering the optimal structures or parameters of a design;

FIG. 7 shows anon-limiting example of a probabilistic program;

FIG. 8 shows a non-limiting example of a workflow for human-machine inference;

FIG. 9 shows anon-limiting example of for inverting a traditional forward data generation model;

FIG. 10 shows a non-limiting example of a causal discovery process;

FIG. 11 shows a non-limiting example of a method for using a module in a Sim-AI OS;

FIG. 12 shows a non-limiting example of a method for generating a prediction; and

FIG. 13 schematically illustrates a non-limiting example of a computer system that is programmed or otherwise configured to implement methods provided herein.

### DETAILED DESCRIPTION

The technology of the present disclosure comprises a Simulation-AI Operation System (Sim-AI OS), and accompanying workflows and dataflows. In some cases, the Sim-AI OS and its accompanying workflows and dataflows can be purpose-built for Simulation Intelligence, general purpose for use across domains for science and intelligence, or both. In some cases, the system of the present disclosure enables optimal, efficient, and novel workflows for several user-groups in fields including, but not limited to, engineering, sciences, and intelligence.

The disclosure further illustrates the integration of a Sim-AI OS in a stack comprising software, hardware, algorithms, mechanistic and data-driven models, and data flows for simulation, AI and ML, scientific computation, decisions intelligence, data analysis, science application, or a combination thereof. This system may provide a common, unified, integrated stack that retains flexibility, modularity, and extensibility for use in Simulation Intelligence and AI/ML. Further, this system may broadly and uniquely enable critical advancements to be made in areas of fundamental AI/ML, including, but not limited to, causality, open-endedness, program synthesis, and human-machine uncertainty reasoning.

In a further aspect of the disclosure, “close to the metal” methods that aim to optimize a given algorithm, method, pipeline, library, programming language etc., may be utilized by writing (or transforming) software in a way that can be near optimal for machine code (regarding time and space efficiencies). This may include, but may not be limited to, the ability to readily implement domain-specific languages (DSL), perform or automate hardware-software codesign, and/or use machine intentional programming (MIP).

In some embodiments, methods enables by the Sim-AI OS and its integration in a stack may comprise parallel computing for multiple physics, multi-physics multi-scale simulations for geoengineering decision-making, simulators as computation graphs for causal reasoning, infrastructure for open-endedness and lifelong machine learning, and/or systems uncertainty quantification and reasoning through multiple modules, levels, and abstractions.

Described herein, in certain embodiments, are systems comprising: a simulation module layer that is configured to be integrated and used in a simulation-artificial intelligence (Sim-AI) operating system (OS), wherein the simulation module layer comprises one or more domain-specific computing modules that are useable for AI-enabled simulations of one or more target applications.

Also described herein, in certain embodiments, are methods comprising: providing a simulation module layer that is configured to be integrated and used in a simulation-artificial intelligence (Sim-AI) operating system (OS), wherein the simulation module layer comprises one or more domain-specific computing modules; and using the one or more domain-specific computing modules for AI-enabled simulations of one or more target applications.

### Certain Definitions

Unless otherwise defined, all technical terms used herein have the same meaning as commonly understood by various approaches to which the present subject matter belongs.

As used in this specification and the appended claims, the singular forms “a,” “an,” and “the” include plural references unless the context clearly dictates otherwise. Any reference to “or” herein is intended to encompass “and/or” unless otherwise stated.

Reference throughout this specification to “some embodiments,” “further embodiments,” or “a particular embodiment,” means that a particular feature, structure, or characteristic described in connection with the embodiment is included in at least one embodiment. Thus, the appearances of the phrase “in some embodiments,” or “in further embodiments,” or “in a particular embodiment” in various places throughout this specification are not necessarily all referring to the same embodiment. Furthermore, the particular features, structures, or characteristics may be combined in any suitable manner in one or more embodiments.

### Simulation Intelligence (SI) Stack

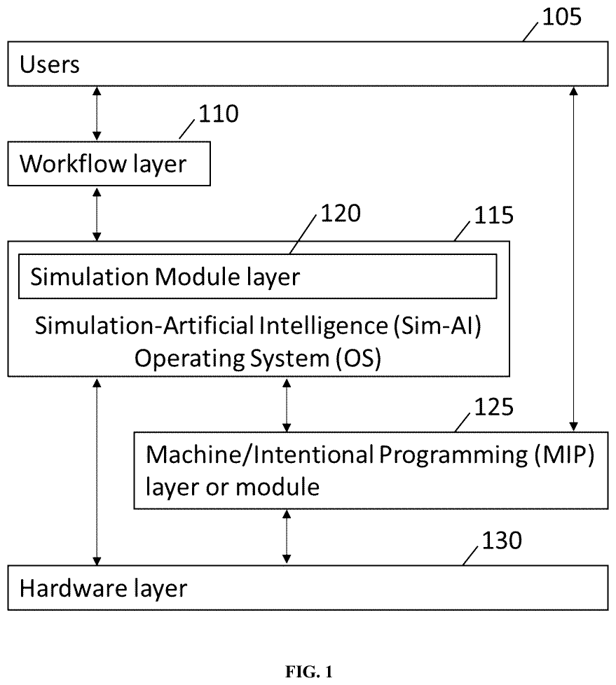

Provided herein is an operating system (OS) and surrounding technologies that may be purpose-built for Simulation Intelligence, as well as general purpose for science and intelligence workflows across domains. Referring to FIG. 1 is an example of a block diagram for a system comprising a simulation-AI (Sim-AI) operating system (OS). The system may comprise a Simulation Intelligence (SI) stack, which may enable optimal, efficient, and novel workflows for several user-groups 105 in engineering, sciences, and intelligence. Users 105 may generally comprise scientists and other researchers in across many domains and across scales (e.g., from particle physics and biology, to material design and drug discovery, to weather and climate science, to socioeconomics and geopolitics, to astrophysics and cosmology), such as, but not limited to, ML/AI scientists and engineers, data scientists, theoreticians, robotic, AI, and automated scientists (or “self-driving laboratories”), intelligence analysts, economists and political scientists, or other domain experts, including policy- and decision-makers (from climate to economics to financial/trading markets). In some embodiments, the SI stack, by example as illustrated in FIG. 1, may comprise modules and interfaces for users 105 to interact at various abstraction levels, such as programmatic and user-friendly interfaces for the top-level workflows 110, the low-level machine programming interfaces and modules 125, flexible and configurable ML and data modules 115.

In some embodiments, the SI stack may comprise a computing and data infrastructure with one or more layers including: a workflow layer 110 (e.g., applications), a simulation-artificial intelligence (Sim-AI) operating system (OS) 115 (e.g., simulation module layer 120), machine/intentional programming (MIP) layer 125, and hardware layer 130 (e.g., compute substrate, such as CPU, GPU, FPGA, etc.). In some cases, the Sim-AI OS 115 may comprise one or more engines (e.g., techniques and/or methods). In some cases, the MIP layer 125 may be any programming interface (e.g., manual or machine programming).

The Sim-AI OS 115 may comprise one or more classes of complementary algorithmic methods that represent foundational techniques for synergistic simulation and AI technologies.

In some cases, the workflow layer 110 may comprise one or more Sim-AI workflows (e.g., applications), which may be the result of the integration with the Sim-AI OS 115. In some instances, the workflow layer 110 may reciprocate information, feedback, and data that informs the development and implementation of Sim-AI OS 115. In some instances, the workflow layer 110 may comprise new scientific and intelligence workflows, such as, but not limited to, automation and human-machine teaming processes (e.g., “active sciencing”, inverse problem solving, etc.). The manifestations of the Sim-AI OS 115 and the SI stack of FIG. 1 may comprise modular and versatile software packages, which as—is can supply the structured layers for the workflows described herein, while also providing a user with flexibility and extensibility to build atop of, and/or swap in custom components.

Further, the information flow illustrated in FIG. 1 may not be first-order or mutually exclusive. There may any number of variations of information flow in the SI stack of FIG. 1.

That is FIG. 1 may represent a general scheme of which there can be numerous variations that may combine methods towards similar information flows and workflows. As an example, a ML researcher may implement pipelines that traverse multiple layers (and information paths). As a further example, if a user who is an engineer is working with machine programming, that engineer may also work with Sim-AI OS methods simultaneously or sequentially.

The SI stack of FIG. 1 may also provide for interfacing and complete pluggability of third party, proprietary, open-source, open-standard, custom, or other types of extensions. Extensions may comprise, by way of non-limiting example, additional machine learning libraries, hardware-software codesigns, software development kits (SDKs), application programmable interfaces (APIs), computation distribution, privacy-preserving algorithms and data pipelines, etc.

A set of technology capabilities, enabled by the present disclosure, which may help scientific endeavors and fields beyond simulation-, intelligence-, and data-related bottlenecks, may include, by way of non-limiting example:
Synergistically combine expert knowledge models (e.g., first principles, mechanistic equations) with data-driven surrogate models
Flexibly combine multiple engines/simulators
Efficient and scalable simulators, operating at multiple levels of fidelity and abstraction
Simulate and learn processes and systems spanning multiple physics and multiple spatial-temporal scales
Capable/reliable simulation and inference with limited data
Validate simulations with real data, and quantify reliability (e.g., uncertainty)
Learn models that reflect the probabilistic causal structures of complex systems
Readily encode domain expertise and causal structure into simulators
Generate counterfactual simulations (e.g., grounded in causality theory) that reliably simulate possible futures over large time scales and high-dimensional, multimodal data
Inverse problem solving in otherwise intractable spaces and domains
Accelerate existing simulators by multiple magnitudes without refactoring or rewriting legacy codebases
Spin up a simulator via direct physical analogy
Provide a catalogue of domain-specific engines and workflows (e.g., for non-ML-experts)
Integrate seamlessly with real-world datasets, and online data streams
Data engineering to ensure reliability, reproducibility, and security
Systems AI: systems engineering and uncertainty reasoning for complex, dynamic combinations of data, software, hardware, and people

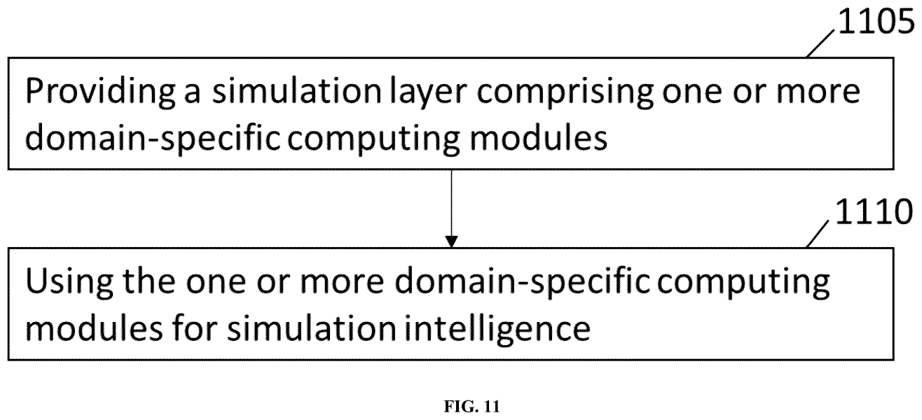

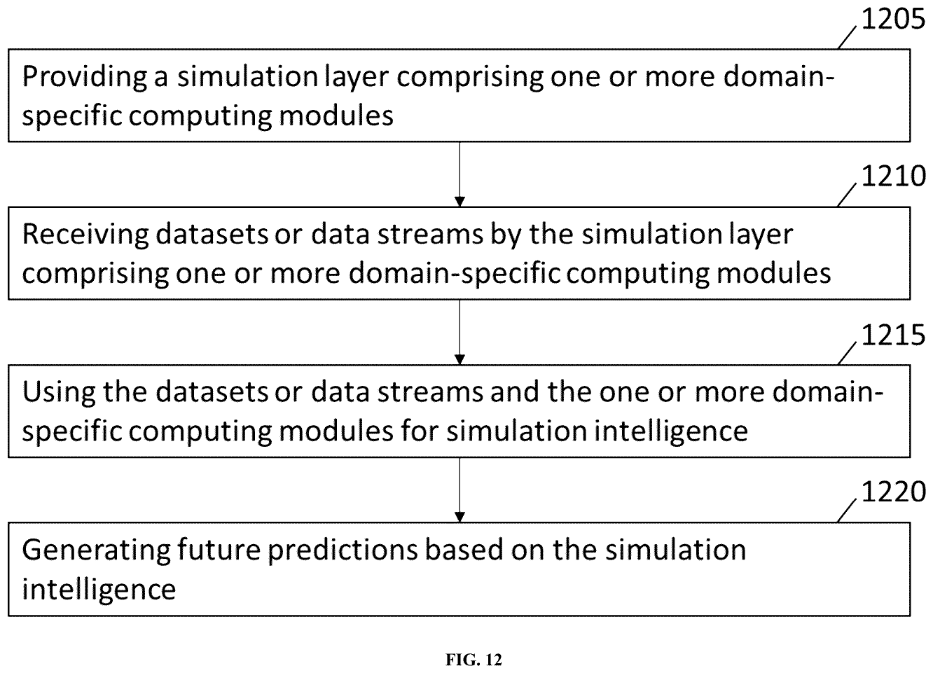

In some embodiments, the SI stack of FIG. 1 may enable a method, for example as illustrated in FIG. 11, comprising: providing a simulation layer comprising one or more domain-specific computing modules 1105 and using the one or more domain-specific computing modules for simulation intelligence 1110. In some cases, simulation intelligence may comprise an AI-enabled simulation, such as those described herein. In further embodiments, the SI stack of FIG. 1 may enable a method, for example as illustrated in FIG. 12, comprising: providing a simulation layer comprising one or more domain-specific computing modules 1205, receiving datasets or data streams by the simulation layer comprising one or more domain-specific computing modules 1210, using the datasets or data streams and the one or more domain-specific computing modules for simulation intelligence 1215, and generating future predictions based on the simulation intelligence 1220. In some cases, simulation intelligence may comprise an AI-enabled simulation, such as those described herein.

### Sim-AI OS Modules

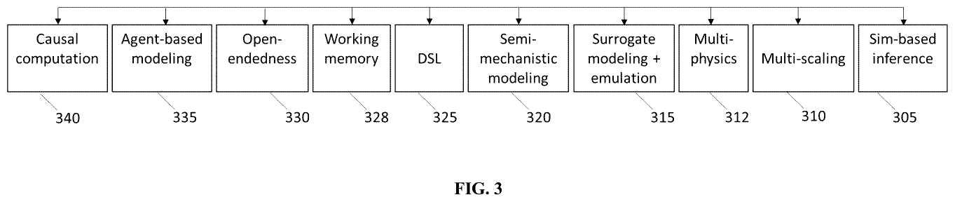

The Sim-AI OS 115 may comprise a simulation module layer 120 that may enable one or more workflows described herein. The simulation module layer 120 may make use of the accelerated computing building blocks in the hardware layer 130. Referring to FIG. 3 is a non-limiting example of modules in the simulation module layer 120. In some embodiments, the simulation module layer may comprise causal computation 340 (e.g., causal ML), agent-based modeling 335, open-endedness 330, working memory 328, domain specific language (DSL) 325 (e.g., SI DSL for probabilistic simulations), semi-mechanical modeling 320, surrogate modeling and emulation 315, multi-physics modeling 312, multi-scale modeling 310 (e.g., spatial and temporal), and simulation-based inference 305. In some cases, the Sim-AI modules may be combined with traditional simulation methods and applications (e.g., computational fluid dynamics (CFD), finite element analysis (FEA) solvers, etc.). In further cases, the Sim-AI modules may be integrated with existing machine learning frameworks and tools (e.g., PyTorch and TensorFlow libraries for tensor modeling and autodiff).

In some embodiments, the simulation module layer may comprise multi-physics 312 and/or multi-scale modeling 310. Multi-physics 312 and/or multi-scale modeling 310 may generally refer to ML and AI-driven simulation that incorporate and integrate multi-scale, multi-physics data in order to increase accuracy and reliability of the model. In some cases, this may uncover mechanisms that explain the emergence of function. This may be in contrast to simulations, which can be widely utilized in domains of science and engineering, yet may often be done in isolation. Further, natural systems (e.g., climate) may involve various types of physical phenomena operating at different spatial and temporal scales. Therefore, simulations which support multiple physics and multiple scales (e.g., spatial and temporal) may provide increased accuracy and usefulness. This may also be true for AI/ML, which can be powerful for modeling multi-modality, multi-fidelity scientific data, yet ML alone (e.g., based on data-driven relationships) may ignore fundamental laws of physics. This can result in ill-posed problems or non-physical solutions.

In further embodiments, physics-informed machine learning methods may integrate mathematical physics models with data-driven learning (e.g., appropriate observational, inductive, or learning biases to steer or constrain the learning process, such as Gaussian processes for capturing physics of dynamic systems). Models for physics-informed ML may include, by way of non-limiting example, physics-informed neural networks, graph-informed neural networks, and probabilistic graphical models (PGMs). PGMs may be useful for encoding a priori structure (e.g., dependencies among model variables in order to maintain physically sound distributions).

In some cases, embedding a PGM (probabilistic graphical models) into the physics-based representation can encode complex dependencies among model variables that arise from domain-specific information. In some instances, this may also enable the generation of physically sound distributions. In such embodiments, the embedded PGM may also identify computational bottlenecks intrinsic to the underlying physics-based model and replace them with an efficient NN surrogate. The hybrid model may thus encode a domain-aware physics-based model that can synthesize stochastic and multi-scale modeling. Further, computational bottlenecks can be replaced by a fast surrogate NN whose supervised learning and prediction can be further informed by the PGM (e.g., through structured priors).

Additionally, since ML models may be ignorant of fundamental laws of physics (e.g., resulting in ill-posed problems or non-physical solutions), an open benchmark for physics-informed ML may approach this challenge in a collective and reproducible way. In some embodiments, benchmarking physics-informed ML methods may require proper parameterized physical models to be explicitly included in the databases. In some embodiments, full-field data in applications of physics and chemistry may be required. In further embodiments, different, problem-specific, physics-based evaluation methods may comprise e.g., metrics for scoring physical consistency and/or spatiotemporal predictions.

In some embodiment, physics-infused ML may be used to model systems with partial information (e.g., to better synergize the two computational fields). In some cases, methods in physics-infused ML may potentially complement physical models to learn missing or misunderstood components of the systems. One such example is Universal Differential Equations (UDEs) in a surrogate modeling motif, as further described herein.

In some embodiments, the simulation module layer may comprise surrogate modeling and emulation 315. A surrogate model may refer to an approximation method which can mimic behavior of an expensive computation or process. In some embodiments, a computationally efficient surrogate model can be trained to represent a system by learning a mapping from simulator inputs to outputs. In such embodiment, the aim of surrogate modeling (also referred to as a statistical emulation) may be to replace simulator code with a machine learning model (e.g., emulator), such that running the model to infer the simulator outputs may be more efficient than running the full simulator itself. An emulator as described herein, may refer to a statistical model of the simulator.

In some instances, mechanistic modeling may be utilized with NNs (or more generally, universal approximator models) in order to allow for arbitrary data-driven model extensions. This may result in a semi-mechanistic approach (e.g., Universal Differential Equations (UDE)), where part of the differential equation contains a universal approximator model. In further instances, Bayesian optimization may be used to design experiments such that the outcomes will be as informative as possible about the underlying process. In such instances, Bayesian optimal experiment design (BOED) may be a powerful mathematical framework across scientific disciplines (e.g., bioinformatics, pharmacology, physics, psychology, etc.).

As an example, hybrid PGM and NN may be used for efficient domain-aware scientific modeling. In such an example, probabilistic graphical models (PGM) may be characterized as structured models for encoding domain knowledge and constraints (contrasted with deep neural networks as data-driven function-approximators). Graph-Informed Neural Networks (GINNs) may be a desirable approach, where PGMs may incorporate expert knowledge, available data, constraints, etc., with physics-based models (e.g., systems of ODEs and PDEs), while computationally intensive nodes in this hybrid model can be replaced by learned features as NN surrogates. Therefore, GINNs may be particularly suited to enhance the computational workflow for complex systems featuring intrinsic computational bottlenecks and intricate physical relations variables. In some cases, the ability for downstream decision-making can be afforded by robust and reliable sensitivity analysis (due to the probabilistic ML approach), and orders of magnitude more computational efficiency may allow for many hypotheses to be simulated and predicted posteriors quantified.

In another example, physical laws may be derived from data-driven surrogates. Simulating complex dynamical systems may rely on governing equations conventionally obtained from rigorous first principles (e.g., conservation laws or knowledge-based phenomenological derivations). Although these equations may be non-trivial to derive, these symbolic or mechanistic equations may be interpretable and understandable for scientists and engineers. However, NN-based simulations, including surrogates, may not be interpretable and can thus be challenging to use (e.g., in cases where it is important the scientist or engineer understand the causal, data-generating mechanisms).

A novel approach for learning ODEs or PDEs from observational data may be referred to as sparse identification of nonlinear dynamics (SINDy). SINDy may select dominant candidate functions from a high-dimensional nonlinear function space based on sparse regression to uncover ODEs that match the given data (e.g., SINDy may provide an ODE surrogate model). This approach may be used in scientific applications (e.g., biological systems, chemical processes, active matter, as well as data-driven discovery of spatiotemporal systems governed by PDEs, etc.). Advances which may be provided in SINDy utilizing methods described in herein may comprise:
1. Synergistic learning deep NN surrogate and governing PDEs from sparse and independent data—A physics-informed deep learning framework may be used to discover governing PDEs of nonlinear spatiotemporal systems from scarce and noisy data accounting for different initial/boundary conditions (IBCs). This approach can integrate the strengths of deep NNs for learning rich features, automatic differentiation for accurate and efficient derivative calculation, and 10 sparse regression to tackle the fundamental limitation of existing methods that scale poorly with data noise and scarcity. The special network architecture design may be able to account for multiple independent datasets sampled under different IBCs (e.g., which may be shown with simple experiments that can still be validated on more complex datasets). An alternating direction optimization strategy can simultaneously train the NN on the spatiotemporal data and determine the optimal sparse coefficients of selected candidate terms for reconstructing the PDE(s). In some embodiments, the NN can provide accurate modeling of the solution and its derivatives as a basis for constructing the governing equation(s), while the sparsely represented PDE(s) in turn can informs and constraints the DNN which can make it generalizable and further enhance the discovery. The overall semi-mechanistic approach (e.g., bottom-up (data-driven) and top-down (physics-informed) processes) may be promising for ML-driven scientific discovery.
2. Sparse identification of missing model terms via Universal Differential Equations—In some embodiments, there may be scenarios where an ML surrogate can be trained for a part of the full simulator system (e.g., for the computationally inefficient or unknown parts). This may also be a use-case of the UDE, replacing parts of a simulator described by mechanistic equations with a data-driven NN surrogate model. In some cases, interpretability and analysis capabilities may be lost at the end of the process of building a UDE (e.g., when an approximation for part of the causal generative model, such as a simulator, may be learned and verified). However, with a knowledge-enhanced approach of the SINDy method, the learned semi-mechanistic UDE back to mechanistic terms that are understandable and usable by domain scientists may be sparse-identified. In some instances, the SINDy algorithm may be modified to apply to subsets of the UDE equation in order to perform equation discovery on the trained neural network components. This may narrow the search space of potential governing equations by utilizing the mechanistic knowledge that was not replaced in training the UDE. Along with the UDE approach in general, this sparse identification method can be further developed and validated with more complex datasets.

The UDE approach may have significant implications for use with simulators and physical modeling, where the underlying mechanistic models may be commonly differential equations. By directly utilizing mechanistic modeling simultaneously with universal approximator models, UDE can be a powerful semi-mechanistic approach allowing for arbitrary data-driven model extensions. In some embodiments, this may yield a synergistic model of domain expertise and real-world data that more faithfully represents the true data-generating process of the system.

Further, surrogate modeling and emulation 315 described herein may provide a transformative approach for ML-augmented scientific modeling. In some embodiments, a practitioner may identify parts of a model and may build a UDE (e.g., when using probabilistic programming (an SI engine motif)). This can be done in a high-level abstraction where the user may not need to write custom inference algorithms. An NN (or other surrogate model such as Gaussian process) may be trained to capture the missing mechanisms. In some cases, NAS and Bayesian optimization approaches may be used to do this in an automated, uncertainty-aware way. The missing terms can be sparse-identified into mechanistic terms. The recovered mechanisms may then be verified to ensure they are scientifically sane and further be verified quantitatively (e.g., extrapolate, do asymptotic analysis, run posterior predictive checks, predict bifurcations, etc.). In some cases, additional data may be gathered to validate the new terms.

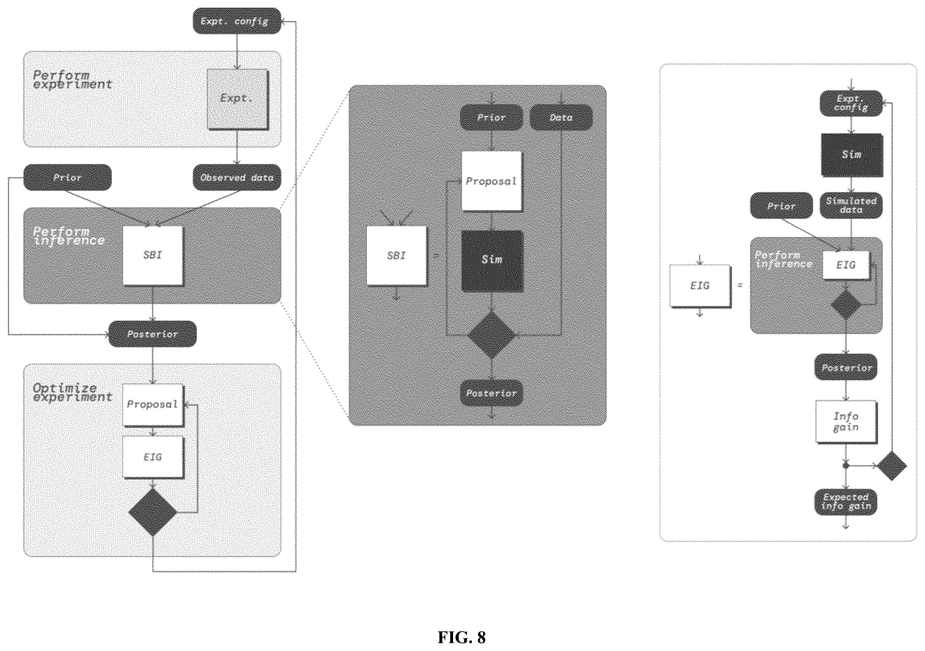

In some embodiments, the simulation module layer may comprise simulation-based inference (SBI) 305. Numerical simulators may be used across many fields of science and engineering to build computational models of complex phenomena. In some aspects, it may be important to consider how to link such simulation-based models with empirical data. As an example, SBI may be used to establish such a link. In some embodiments, further development of SBI methods may comprise human-machine inferences. In some cases, human-machine inferences may comprise an efficient and automated loop of the scientific method (e.g., for sufficiently well posed problems). Referring to FIG. 8, the workflows for human-machine inference is schematically illustrated. In some cases, human-machine inference may be referred to as active science with simulation-based inference methods. In some instances, as described in FIG. 8, the overall process may comprise operations to (1) perform experiment, (2) perform inference, (3) optimize experiment, and (4) repeat from (1). This approach may provide an efficient method of physical experiments, particularly for expensive experiments in large search and hypothesis spaces (e.g., Large Hadron Collider at CERN). This may allow for simulation intelligence to broaden the scientific method. In some cases, this SI-based science workflow may be advanced by replacing the information gain objectives with open-ended optimization.

In some embodiments, the simulation module layer may comprise causal computation 340 (e.g., causal ML, causal reasoning, causal discovery, etc.). Standard approaches in statistical analysis and pattern recognition may draw conclusions based on associations among variables and learned correlations in the data. In some embodiments, these approaches may not suffice when scientific queries are of causal nature rather than associative (e.g., there is marked distinction between correlations and cause-effect relationships). Simulators may provide virtual testbeds for the exploration of complex real-world scenarios, and, if built with the tooling for causal machine learning (e.g., specifically counterfactual reasoning), can provide “what-if” analyses in an efficient and cost-effective way. In some cases, each run of a simulator may be a realization of a particular possible world, and counterfactual what-if claims can be studied by varying independent parameters of the model and re-running the simulation. In some cases, causal reasoning may comprise a causal discovery process, which may be an active causal discovery process.

Given simulator execution traces may consist of states, events, and actions, which can define causal relationships based on these entities (e.g., provide simulation-based definitions of causality). In some cases, without this grounding, reliable causal claims may not be made. As an example, a practical formulation: event C causes event E in an actual trace w if and only if there exists a counterfactual trace π′ that is similar enough to π, which requires that neither C nor E happens in the same state in which they happened in π. This suggests counterfactual analysis can be performed by searching all traces produced by the simulator for counterfactual π′, but this may be intractable for a non-trivial simulator. However, if the trace is intervened during the simulation process, a variety of counterfactual traces can be generated with slight differences in events, such that the causal relationships between events may be reasoned. It follows that this approach can be called intervention-based counterfactual analysis.

Simulation traces can be complex, amounting to several forms of causation based on the occurrence and omission of events in trace π:
1. Basic causation—In order for event A to cause event B (A→B), A's occurrence has to be both sufficient and necessary for B in π. That is, for the mathematically inclined reader, A→B≡(A⇒B)∧(B⇒A)≡A⇔B.
2. Prevention—In order for event A to prevent event B, A's occurrence has to be both necessary and sufficient for B's omission. That is, A→B≡(A⇒¬B)∧(¬B⇒A)≡A⇔¬B.
3. Transitivity—If A causes B and B causes C then A causes C.
4. Causation by omission—If A's omission is both necessary and sufficient for B's occurrence and we accept that omissions are allowed to be causes, then A's omission can be considered to cause B's occurrence.
5. Prevention by caused prevention—It follows from the prior causal claims that if A causes B and B prevents C, then A prevents C.

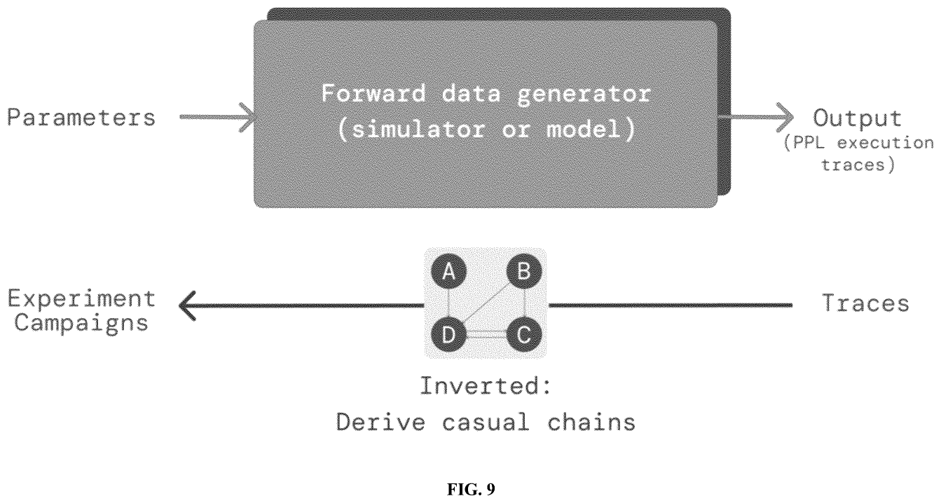

Referring to FIG. 9, an example of a traditional forward data generation model is illustrated to learn what causes may have produced the observed effects. In some embodiments, parameters may be used in a forward data generator (e.g., simulator, model, etc.) in order to generate an output. In some cases, the parameters may be used in a forward generator to further recover the execution traces for causal reasoning. In some cases, the output may comprise probabilistic programming language (PPL) execution traces. Further, traces may be inverted to derive causal chains to generate experiment campaigns. A described herein, a simulator may aim to encode the cause—to effect data generation process. In practice, simulators that enable this cause-effect inversion learning may represent a new workflow that can broaden the scientific method.

The execution of a simulator can result in one or more simulation traces. This may represent various paths of traversing the state space given the underlying data-generating model, which may be not unlike the execution traces resulting from probabilistic programming inference. By formalizing the sequence of simulator states as trace-based definition of causal dependencies, the computational and mathematical tooling to make causal inquiries may be obtained. Further, with a simulator that produces a full posterior over the space of traces, as in probabilistic programming, causal conclusions may be drawn with causal inference and discovery algorithms.

As an example, causal computation 340 may be used for active causal discovery. In some embodiments, asking the causal questions may require a causal model to begin with. The problem of inferring such a model from observational, interventional, or mixed data may be referred to as causal discovery. In some cases, dedicated causal discovery algorithms may be separated into subtypes, such as constraint-based and score-based. The constraint-based algorithms can construct the causal structure based on conditional independence constraints, while the score-based algorithms can generate a number of candidate causal graphs, assign a score to each, and select a graph based on the scores.

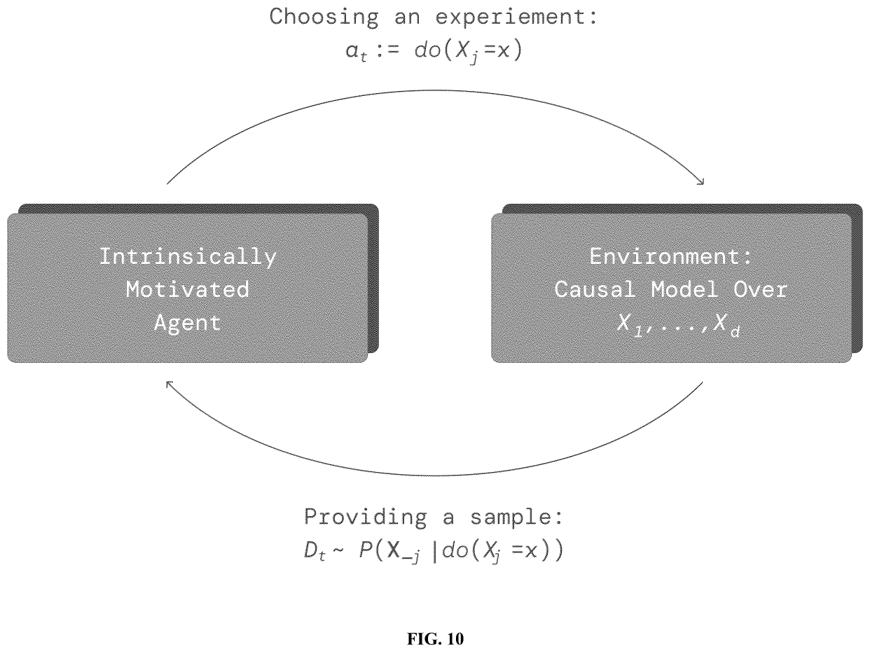

In the present disclosure, active causal discovery may illustrate a method that can be a novel “human-machine teaming” workflow. The setting for active causal discovery can involve an agent iteratively selecting experiments (or targeted interventions) that are maximally informative about the underlying causal structure of the system under study. This experiment process is shown in FIG. 10. Referring to FIG. 10 is an active causal discovery. FIG. 10 may be an active Bayesian causal discovery, where an in silico agent iteratively experiments with its simulation environment in order to learn a structured causal model. This simplified diagram illustrates, by example, a causal model learned over observed variables, where the agent actively intervenes on some of the variables to derive cause-effect relationships. In some embodiments, at each iteration an agent may, 1. perform an experiment in the form of intervening on one of the variables and fixing its value, do (Xⱼ=x); 2. observe the outcome by sampling from the interventional distribution P(X₋ⱼ|do(Xⱼ=x)); 3. update its beliefs with the observed outcome; and 4. plan the next experiment to maximize information gain (or similar criteria).

In some instances, this process may be repeated until the agent converges on a causal world model (with sufficient confidence) or an experiment threshold is reached. In short, the do-operator may force a variable to take a certain value or distribution, which is distinct from conditioning that variable on a value or distribution. This distinct operation can allow for estimates of interventional distributions and causal effects from observational distributions (under certain conditions).

Further, the active learning approach with targeted experiments can allow for uniquely recovering the causal graph, whereas scoreor constraint-based causal discovery from observational data may struggle going beyond the Markov equivalence class. In the simulation setting, virtual agents can exist, while real scientists can follow the same procedures in the lab, potentially to minimize the experiments on costly equipment. In some examples, there may be variations involving human-machine teams to iterate over causal models and interventions (e.g., in silico and in situ). Further, a driving simulator may be built for causal reasoning, as described herein, which may comprise robust and reliable simulation tools to help address that the true counterfactual outcome is not observed in counterfactual (and causal) reasoning.

Causal reasoning may facilitate the simulation of possible futures and prediction of intervention outcomes, leading to more principled scientific discovery and decision-making. In some embodiments, causal reasoning may be integrated with probabilistic programming. Probabilistic programming as a formalism for causal reasoning, as a natural representation framework may enable probabilistic causal reasoning. In some cases, combining probabilistic causal reasoning and causal optimization, may enable causal inference with Bayesian optimization which may offer new, improved approaches for decision making under uncertainty.

In some embodiments, the simulation module layer may comprise agent-based modeling (ABM) 335. In some embodiments, systems may be modeled as collections of autonomous interacting entities (or agents) with encapsulated functionality that operate within a computational world. In some cases, ABM agents can represent an individual. In some cases, ABM agents can represent collective entities (such as organizations or groups). An example of an agent may comprise skilled and unskilled workers at varying class-levels in a city environment in an artificial economy simulation for quantitatively exploring consequences of policy decisions. In an alternative example, an agent may comprise individual bacteria may be modeled as agents from population statistics obtained with flow cytometry. In some embodiments, ABMs may be able to generate system-level behaviors that cannot have been reasonably inferred from, and often may be counterintuitive to, the underlying rules of the agents and environments alone. This may allow for simulation-based discovery of emergent phenomena in many systems at all scales, including, but not limited to, particle physics, quantum chemistry, energy, transportation systems, climate, and cosmology.

In one aspect, an example of ABM may comprise optimizing economic policies. In some cases, such a model may aim to promote social welfare through the design of optimal tax policies in dynamic economies using, for example, ABM and/or deep RL. The model may use a principled economic simulation with both workers and a policy maker (e.g., individual agents and a planner, respectively), all of whom are collectively learning in a dynamic inner-outer reinforcement learning loop. Such a model may provide a framework for integrating economics theory with data-driven simulation, which can produce transparent and objective insights into the economic consequences of different tax policies. Further, the framework may be improved with counterfactual reasoning for what-if experimentation. This may comprise a key value-add of AI-driven simulators.

In another aspect, an example of ABM may comprise simulating networked acts of violence, which may comprise seemingly random and chaotic human events (e.g., insurrections and other acts of violence). In some embodiments, reliable simulations may utilize real-world data in a way that can complement and validate the theory. In cases, the simulation may be implemented with a semi-mechanistic modeling approach that can coordinate both mechanistic equations (e.g., information theoretic models of disinformation) and data-driven function approximations. In some instances, building this ABM framework in a generative modeling (e.g., comprising probabilistic programming) way may be essential for simulating the multitudes of outcomes and their full posteriors. The probabilistic programming approach may also behoove counterfactual reasoning, or quantifying the potential outcomes due to various courses of action.

Further provided herein are fields for expanding artificial intelligence, such as, for example, open-endedness 330. Open-endedness or open-ended search, as referred herein, may comprise an algorithm that can consistently produce novelty or increase in complexity in its outputs.

Open-ended learning algorithms may be those with characteristics of life-long learning, such as, but not limited to, adaptively and continually pose new objectives, adapt to environment changes, and avoid pitfalls such as local minima, deceptive loss functions. In some embodiments, open-ended algorithms may seek to increase complexity, thereby increasing uncertainty. In some cases, this may be desirable property in optimization (and intelligence) as it may be a source of robust behavior and mechanistic innovation. In some instances, open-endedness may comprise processes that do not stop. In some instances, open-endedness may comprise processes that do not have specific objectives.

In some embodiments, curiosity, novelty quality-diversity, and memory augmentation algorithms may in practice be quite limited in the kinds of complexity they generate, in contrast to simple biological systems (e.g., bacteria, such as E. coli). Further, the approaches for working, short term, and long term memories may remain limited compared to the observed characteristics of their biological counterparts. Therefore, open-endedness may comprise a ripe area for extending the domain of artificial intelligence, where complexity sciences will have significant roles to play. In some cases, open-endedness may be used in the field of artificial life (e.g., referred to as ALife), which studies artificial systems which exhibit the general characteristics of natural living systems.

In some embodiments, a fully implemented open-ended system can mean not only solving optimization problems as posed by practitioners, but also posing new questions or approaches for practitioners to themselves consider. In some instances, this may also allow AI systems to leverage their learned expertise to create new problem formulations, or insights, and eventually, scientific theories.

### Sim-AI OS Engine

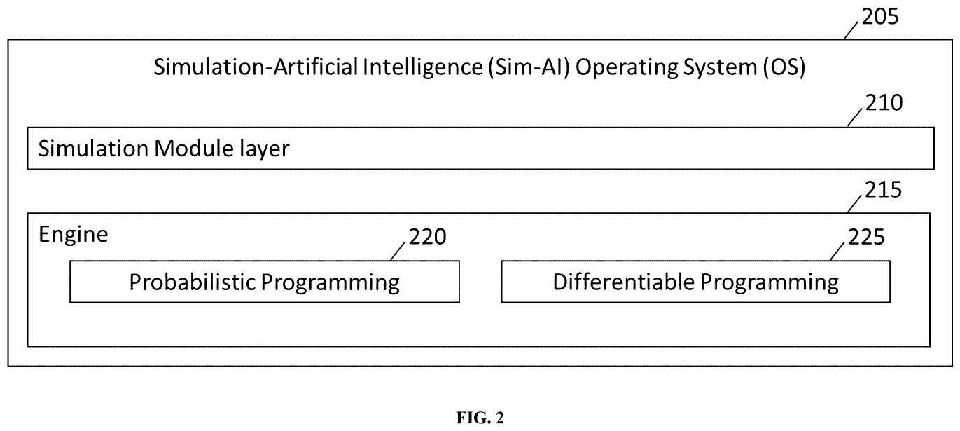

Referring to FIG. 2, the modules in the simulation module layer 220 of the Sim-AI OS 205, may be built using an engine 215 (e.g., techniques and/or methods). In some embodiments, the engine 215 may comprise a probabilistic programming 220 framework, differentiable programming 225 framework, or a combination thereof. In some embodiments, the two frameworks referred to herein may comprise overlaps or interconnections (e.g., probabilistic programming languages can use the autodifferentiation mechanisms in differentiable programming).

In some embodiments, the engine 215 may comprise a probabilistic programming 220 framework. Probabilistic programming may be used to expand the scope of probabilistic graphical models (PGM) by allowing for inference over arbitrary models as programs (e.g., programming constructs such as recursion and stochastic branching). Probabilistic programming may enable generative models to be easily written and experimented with. In some cases, the probabilistic programming (PP) paradigm may equate probabilistic generative models with executable programs. Probabilistic programming languages (PPL) can enable practitioners to leverage the power of programming languages to create rich and complex models, while relying on a built-in inference backend to operate on any model written in the language. This decoupling may be a powerful abstraction because it can allow practitioners to rapidly iterate over models and experiments, in prototyping through deployment. The programs may be generative models, since they can relate unobservable causes to observable data, to simulate how we believe data is created in the real world.

Analogously, differentiable programming is a generalization of neural networks and deep learning, allowing for gradient-based optimization of arbitrarily parameterized program modules.

These can provide a much more expressive toolkit of knowledge representation.

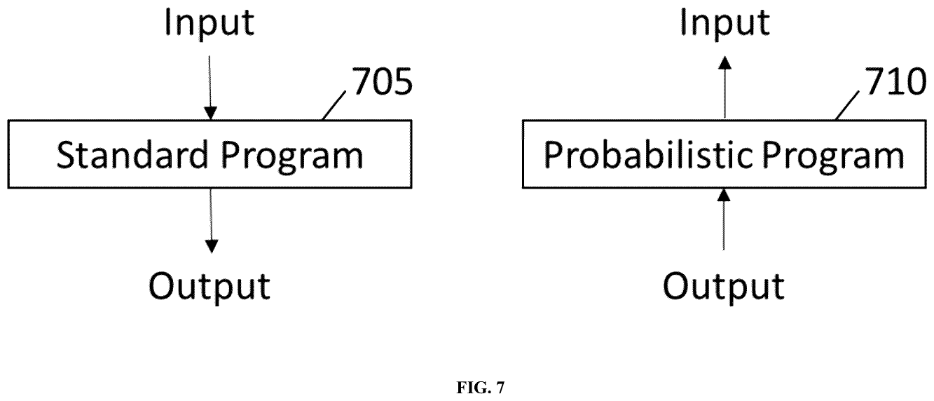

Referring to FIG. 7, with a probabilistic program, a joint distribution p(x, y) of latent (unobserved) variables x and observable variables y may be defined. PPL inference engines may produce posterior distributions over unobserved variables given the observed variables or data, p(x|y)=p(y|x)p(x)/p(y). As observed variables may correspond to the output of a program, probabilistic programming 710 may provide a way to “invert” a given program, meaning it may infer a program's inputs given an instance of data that corresponds to the program's output. This may be in contrast to a standard program 705 which may take an input to generate a corresponding output.

In some embodiments, probabilistic programs may be used as simulators. In some cases, a probabilistic program may itself be a simulator, as it can express a stochastic generative model of data. In such cases, given a system or process sufficiently described in a PPL, the forward execution of the program can produce simulated data. In some examples, a simulator can be run forward to predict the future, yet with a probabilistic program parameters may be inferred based on the outcomes that are observed. As an example, a neurodegeneration program may define a statistical model with random samplings, from which probabilistic disease trajectories may be generated and parameters may be inferred for individual biomarkers.

Further, simulating with probabilistic programs can, for semi-mechanistic modeling, where Turing-complete PPL can provide flexible modeling for integrating physical laws or mechanistic equations describing a system with data-driven components that may be conditioned or trained on data observations. In some instances, PPL may enable semi-parametric modeling, where an inference engine can handle programs that combine parametric and nonparametric models. In such instances, the parametric component may learn a fixed number of parameters and may allow a user to specify domain knowledge, while a nonparametric model (e.g., a Gaussian process) can learn an unbounded number of parameters that grows with the training data. These two programming features—semi-mechanistic and semi-parametric modeling—along with the overall expressiveness of PPL may be well-suited for non-ML specialists to readily build and experiment with probabilistic reasoning algorithms.

In some examples, PPL and DP may be used for “partially specified” models, which comprise black-box (e.g., deep learning) and fully-specified simulators. In further examples, PPL ue may be advanced and scaled in simulation-based inference. This may be the case particularly in the context of human-machine inference. Using probabilistic programs as the simulator may provide advantages, such as, but not limited to, modularity in modeling systems, general-purpose inference engines, uncertainty quantification and propagation, and interpretability.

In some embodiments, the engine 215 may comprise a differentiable programming 225 framework. Differentiable programming (DP) may comprise a programming paradigm in which derivatives of a program can automatically be computed and used in gradient-based optimization in order to tune the program to achieve a given objective. DP may be used in a wide variety of areas, such as scientific computing and ML. In some embodiments, DP can be viewed as a generalization of deep learning. In some cases, the potential of DP may be immense when taken beyond deep learning to the general case of complex programs. In some instances, existing programs may take advantage of an extensive amount of knowledge embedded within them. In some instances, this may enable novel models to be produced and in silico experiments to be conducted.

In some examples, DP tied to ML and simulation may be used to derive techniques for working with non-differentiable functions like ReLU used in deep learning or with non-smooth functions. It some examples, it may also be useful to work with approximate reals, rather than reals, and to seek numerical accuracy theorems. In further examples, particularly in ML, it may be important for DP to add explicit tensor (multi-dimensional array) types with accompanying shape analysis. Further, richer DP languages may support wide ranges of types and computations (e.g., recursion, or programming with Riemannian manifolds (to accommodate natural gradient descent)). In some instances, Julia, C++ (e.g., DiffTaichi), and close-to-the-metal domain-specific languages may be used to make computation runtimes magnitudes more efficient.

### Sim-AI Workows

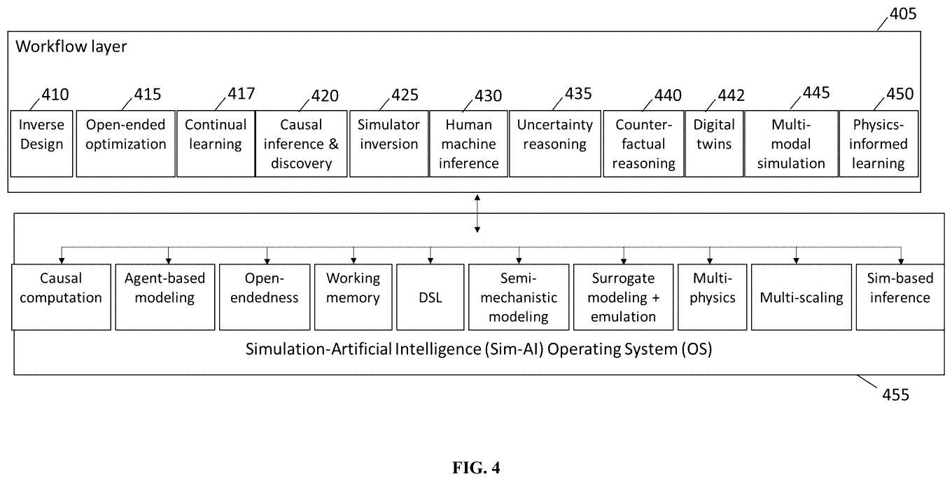

Referring to FIG. 1, the Sim-AI OS layer 115 may be communicably coupled to the workflow layer 110. In some embodiments, the modules and engines of the Sim-AI OS layer 115 may enable one or more workflows (or applications) of the workflow layer 115. Referring to FIG. 4 is a non-limiting example of workflows in the workflow layer 405, which may be enabled by one or more modules of the Sim-AI OS 455. In some embodiments, the workflow layer 405 may comprise inverse design 410 (also referred to as inverse problem solving), open-ended optimization 415, continual learning 417, causal inference and discovery 420, simulator inversion 425, human machine inference 430 (also referred to as active science), uncertainty reasoning 435, counterfactual reasoning 440, digital twins 442 (e.g., with live data), multi-modal simulation 445, and/or physics-informed learning 450. In some examples, a workflow may comprise online and dynamic optimization.

In some embodiments, the pathway between users 105, such as scientists and domain experts, and the workflow layer 110 may comprise valuable for practical use. For example, for AI and ML scientists and engineers, this can be a critical path for developing and utilizing the Sim-AI OS 115 and workflow layer 110. The users 105 may further comprise many expertise and interest areas, where users may interact with any layer and component (e.g., software infrastructure engineers working directly with HPC at the lower hardware level, ML scientists working directly on probabilistic programming or open-endedness without the context of a workflow, etc.).

The modules and engines in Sim-AI OS of the present disclosure may enable, in some embodiments, for inverse problem solving 410. An inverse problem may generally refer to a problem comprising inferring hidden states or parameters from observations or measurements. For example, if the forward simulation (or data-generation) process is x→y, x may be inferred given y. In scientific settings, an inverse problem may comprise the process of calculating from observations the causal factors that produced them. Classical inverse problems, may include, image reconstruction (e.g., MRI reconstruction, CT tomographic reconstruction, etc.), inverse scattering, and computed tomography. Further, computational image reconstruction methods may be classified as direct, analytical, or iterative reconstruction. Based on knowledge and information, a forward model can be derived to predict data given an underlying objective, either a simulation model or a mathematical/physical model. The reconstruction may be addressed by computing the mathematical inverse of the forward model via nonlinear programming and optimization with regularization. In some embodiments, a deep learning based approach may provide a way to inverse problem solve when conventional mathematical inversion may be challenging. In some cases, rather than relying on an accurate physics or mathematical model, the new data-driven machine learning methods can leverage large datasets to learn the inverse mapping end-to-end.

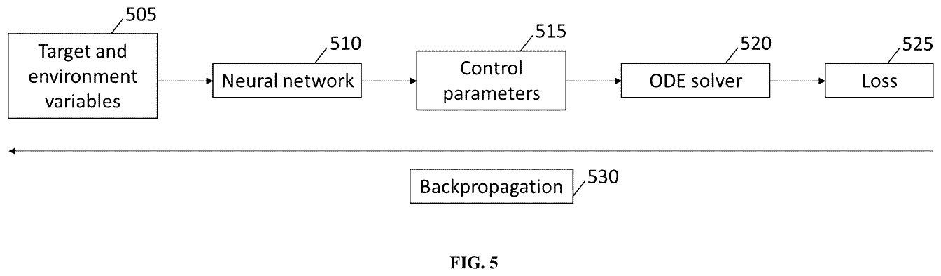

In further embodiments, inverse-problem solving may be used for the design of new materials and devices, as well as for the discovery of novel molecular, crystal, and protein structures via an inverse process. FIG. 5 illustrates a non-limiting example of a block diagram for inverse problem solving with a differentiable programming engine. This may be used for inferring hidden states or parameters from observations or measurements. Further, errors or gradients may be propagated throughout the end-to-end software.

an example of coupling a neural network surrogate 510 with a simulator (as an ODE solver) 520 to solve an inverse problem or inferring hidden states or parameters from observations or measurements. Referring to FIG. 5, the problem of inferring hidden states or parameters from observations or measurements 505, for instance given an environment situation (e.g., wind, target, etc.), may require solving for optimal control parameters 510 (e.g., angle, weight, etc.) for the physical system (e.g., represented by a Sim-AI based simulator). In some embodiments, the target and environmental variable 505 may be fed into a neural network 510, which may then generate control parameters 515. The control parameters 515 may then used for the physical system, represented as an ODE solver 510, which can then be used to determine loss 525. The loss 525 can then be used for backpropagation 530 of the forward process. In some cases, differentiable programing as described herein may enable this approach because the end-to-end differentiable workflow, including both simulation code and ML model, can backpropagate errors and make updates to model parameters.

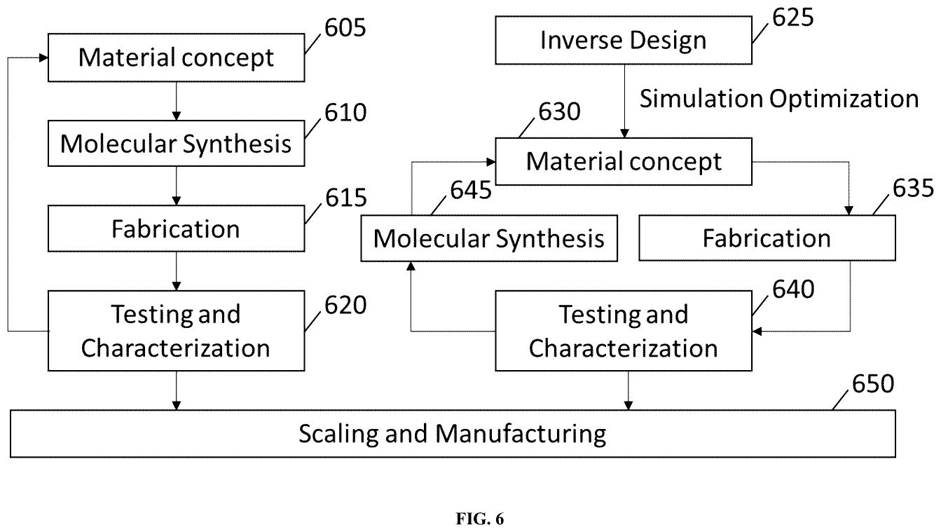

Further, inverse problem-solving may be used in a problem of inverse design, for example, by discovering the optimal structures or parameters of a design based on the desired functional characteristics. As an example, computational inverse design approaches may have many use-cases in optimizing nanophotonics and crystal structures. An non-limiting example of block diagram for discovering the optimal structures or parameters of a design is shown in FIG. 6. The block diagram of FIG. 6 may also be used for inverse design with Sim-AI based simulation, modeling, and/or optimization. In some cases, inverse design cycles can replace existing, deductive paradigm that can be expensive and inefficient, and yield suboptimal solutions. In some instances, in complex spaces like materials science, inverse design can yield de novo molecules, foreshadowing what can be an SI-driven, inductive scientific method.

Referring to FIG. 6, optimal structures or parameters of a design are uncovered based on desired functional characteristics, for instance searching for the optimal molecular configurations for energy storage materials. The current material discovery paradigm (e.g., for organic redox flow batteries) is shown in FIG. 6. This paradigm may begin with a material concept 605, followed by its molecular synthesis 610, its fabrication 615, and its testing and characterization 620. In some cases, the testing and characterization 620 may be followed by updated the material concept 605. Further, once testing and characterization 620 is completed, scaling and manufacturing 650 of the material may performed.

This paradigm can be in contrast to a closed-loop, inverse design counterpart in silico that can maximize efficiency and minimize in situ resource-utilization. In this closed-loop process, the first operation may comprise inverse design 625 of the material based, for example, on desired properties or characteristics. This may be followed by a simulation optimization process in order to arrive at a material concept 630. The material concept 630 may be followed by fabrication 635, as well as testing and characterizations 640. In some cases, testing and characterizations 640 may yield desired results and scaling and manufacturing 650 of the material may performed. In some cases, testing and characterizations 640 may be followed by molecular synthesis 645 if any changes to the material are desired. In instances, this may be followed rethinking or evaluating the material concept 630 once again.

In some embodiments, inverse design may differ from conventional inverse problems with several unique challenges in scientific exploration. In some cases, the challenge may be that the forward operator is not explicitly known. In some instances, the forward operator can be modeled by first-principles calculations (e.g., molecular dynamics and density functional theory (DFT)). This may make inverse design intractable to leverage recent advances in solving inverse problems, such as MRI reconstruction, implanting on images through generative models with large datasets. In further cases, the search space may be intractably large. In some examples, small drug-like molecules may contain between about 1000 to 2000 unique cases, while solid materials may have an even larger space. This may result in obvious obstacles for using global search (e.g., Bayesian optimization, evolutionary strategies, Bayesian inference via Markov Chain Monte Carlo (MCMC), etc.) since either method can be prohibitively slow for high-dimensional inverse problems. In further cases, multi-modal solutions with one-to-many mapping may be encountered. In other words, there may be multiple solutions that match the desirable property. This may lead to difficulties in pursuing all possible solutions through gradient-based optimization, which may converge to a single deterministic solution and is easy trapped into local minima. In some instances, probabilistic inference can also have limitations in approximating the complex posterior, which may cause the simple point estimates (e.g., maximum a posterior (MAP)) to have misleading solutions. Suitable inverse design methods may include, but are not limited to, Bayesian and variational approaches, deep generative models, invertible learning, and surrogate-based optimization.

Bayesian and variational approaches may be used for solving inverse design problems, from an inference perspective, since they can be achieved by estimating the full posterior distributions of the parameters conditioned on a target property. Bayesian methods (e.g., approximate Bayesian computing, etc.) may be suited to model the conditional posterior.

However, in some examples, this may encounter various computational challenges in high-dimensional cases. Alternatively, variational approaches (e.g., conditional GANs, conditional VAEs, etc.) may be used to enable the efficient approximation of the true posterior by learning the transformation between latent variables and parameter variables. In some cases, the direct application of both conditional generative models for inverse design may require a large number of data.

Deep generative models may be used for solving inverse design problems. In some examples, the full distributional recovery via variational inference may be studied by producing a point estimate. In further examples, image inverse problems may be studied with a normalizing flow which can be achieved by proposing a formulation that views the solution as the maximum a posteriori estimate of the image conditioned on the measurements. As an example, in MRI or implanting on images, explicit forward operator may be used to provide a strong baseline method.

Surrogate-based optimization may be used for solving inverse design problems by, for example, building a neural network surrogate and then conducting surrogate-based optimization via gradient descent. In some cases, a forward model may be time-consuming, so a faster surrogate can enable an intractable search. In some embodiments, a surrogate-based optimization may comprise neural-adjoint (NA) method, which may directly search the global space via gradient descent starting from random initialization. In some cases, a large number of interactions may be required to converge and its solutions are easily trapped in the local minima. In some instances, the NA method may increase the computational cost, especially for high-dimensional problems.

Invertible models and learning may be used for solving inverse design problems. In some embodiments, flow-based models, may be used to infer the posterior by training on invertible architectures. In some cases, inverse model approaches may suffer from limitations, such as not fully exploring the parameter space, leading to missed potential solutions, and failing to precisely localize the optimal solutions due to noisy solutions and inductive errors (e.g., in materials design problems). In some embodiments, invertible models may be improved by accelerating the inverse design process by leveraging probabilistic inference from deep invertible models and deterministic optimization via gradient descent. In some cases, given a target property, the learned invertible model can provide a posterior over the parameter space (e.g., these posterior samples may be identified as an intelligent initialization which enables us to narrow down the search space). In such cases, a gradient descent may be performed to calibrate the inverse solutions within a local region. In some instances, a space-filling sampling can be imposed on the latent space to better explore and capture all possible solutions.

In some embodiments, a simulation may be implicitly defined as a distribution p(X, Z|y), where X refers to the observed data, Z are unobserved latent variables that take on random values inside the simulation, and y are parameters of the forward model. In some cases, there may be many use-cases and workflows for the inverse, Z or y may be inferred from the observations X=x. The inverse design loop in FIG. 6 may represents a class of this problem.

In some instances, it may be possible the solution to the inverse problem is ill-posed and small changes in observed outputs can lead to large changes in the estimate, implying the inverse problem solver may have high variance. Therefore, uncertainty quantification may be included for scientific applications. This may be true given limited datasets from high-fidelity simulations or experiments. Further, to fully assess the diversity of possible inverse solutions for a given measurement, an inverse solver may be able to estimate the complete posterior of the parameters (conditioned on an observation). This may help to quantify uncertainty, reveal multi-modal distributions, and identify degenerate and unrecoverable parameters. In some embodiments, inverse problems may also be key in the context of causal discovery in science.

Formalisms connecting these challenges, based on the foundations of algorithmic probability, may comprise a framework where the parallel simulation of a large number of computable programs can be used as generative models.

The modules and engines in Sim-AI OS of the present disclosure may enable, in some embodiments, for uncertainty reasoning 435. Simulators and AI systems may comprise a myriad unreliable components (e.g., noisy and faulty sensors, human and AI error, unknown or incomplete material properties, boundary conditions, etc.). Therefore quantifying these myriad uncertainties, propagating them throughout a system, and arriving at a notion or measure of reliability may provide value. In some embodiments, the development of robust AI and simulation systems require careful consideration of dynamic combinations of data, software, hardware, and people. AI and simulation systems in sciences and decision-making can often construct human-machine teams and other variations of cooperative AI, where it can be valuable to calculate the various uncertainties in communications between combinations of humans, machines, agents, and sources of data and information broadly. Additionally, uncertainty reasoning may be used to investigate how the motifs described herein provide more powerful uncertainty methods than currently used in probabilistic ML, for instance the use of differentiable programming (more specifically autodifferentiation) towards automatic uncertainty quantification.

In the present disclosure, the Sim-AI OS modules may comprise significant and valuable overlap between one another. Such overlap provides a valuable framework for integrating such modules. Non-limiting examples of integration of modules may comprise the use of multi-scale and agent-based modeling (e.g., in systems biology, sociopolitics, etc.), the use of physics-infused ML for building surrogate models in multi-physics scenarios, using simulation-based causal discovery in agent-based network models, or semi-mechanistic methods implemented for multiphysics modeling. In some embodiments, one or more elements of the simulation module layer 210 may be combined with one or more elements of the engine 215. In some embodiments, the SI stack of the present disclosure comprises a purpose-build framework for integrating the motifs (e.g., modules or engines) described herein. Table 1 provides a non-exhaustive look of the domains for use-inspired research per motif with various methods and use-cases arise from the integrations of motifs.

In some embodiments, casual surrogates and physics-infused learning may be integrated 420. In such embodiments, a system of differential equations may be viewed as encoding causal mechanisms of physical systems. As an example, the system of differential equations dx/dt=g(x) where x, x(0)=x₀, and g(x):=nonlinearity. The Picard-Lindelof theorem may states there can be a unique solution as long as g is Lipschitz, implying that the immediate future of x can be implied by its past values. With the Euler method, this can be expressed in terms of infinitesimal differentials: x(t+t)=x(t)+dtg(x). This may represent a causal interpretation of the original differential equation as one can determine which entries of the vector x(t) may cause the future of others x(t+dt). A generalization of this approach in the context of algorithmic probability may cover all computable functions, including differential equations and mathematical models. In some cases, differentiability may bot be needed to perform an effective search optimization. The implication may than be that the algorithmic or physics-infused ML methods can represent the causal dynamics of physical systems, whereas neural networks fundamentally may not, and differentiability may not be the essential feature believed to allow neural networks to minimize loss functions. This may provide theoretical grounding that algorithmic and physics-infused ML can be used as causal surrogate models, which may be a more accurate representation of the true causal (physical) processes than universal function approximators (e.g., physics-informed neural networks). This insight may also suggest that using algorithmic physics-infused surrogates may provide grounded counterfactual reasoning.

Several such approaches may comprise, but are not limited, continuous-time neural networks, physics-infused Gaussian processed in causal discovery, and algorithmic information dynamics (AID).

The modules and engines in Sim-AI OS of the present disclosure may enable, in some embodiments, for open-ended search and optimization 415 for de-novo solutions with SI motifs. Open-ended search and optimization may comprise the potential to discover entirely novel solutions in spaces that otherwise may never have been explored. In some examples, such as in socioeconomics as a variation on the multi-scale agent-based modeling framework, the dynamic optimization scheme can suggest an alternative to convergence criteria and can be extended with open-ended search algorithms. In some further examples, AI and simulation tools, such as those described herein, may be used to search for de novo solutions (e.g., by pursuing “materials acceleration platforms” for autonomous experimentation in chemistry). In some cases, this may allow for advancing materials acceleration platforms with SI motifs. In some instances, new approaches to machine learning and robotics systems may be used to support open-endedness (e.g., continual learning or an alternative flow of information for open-ended algorithms).

### Hardware Lavers

Referring to FIG. 1, implementations of the Sim-AI OS modules and engine components 115, such as those described herein, can take advantage of available computing resources while also informing the design of new computing architectures. In some embodiments, the Sim-AI OS 115, as well as a MIP layer 125 may be communicably coupled to a hardware layer 130 to enable SI as described herein. In some cases, the SI stack may comprise one or more hardware layers. In some embodiments, the Sim-AI pipelines described herein can be implemented at scale on high performance computers (HPC) and supercomputers, on a simple 4-CPU laptop, anything in between, or a combinations thereof. In some embodiments, the Sim-AI pipelines can be implemented on a centralized network, a decentralized network, a distributed network, or a combination thereof. In some cases, the network may comprise a cloud comprising one or more servers.

In some embodiments, the hardware interfacing layer (e.g., machine/intentional programming 125 and DSL) can add a useful abstraction between low-level compute hardware and other layers, modules, and users. In such embodiments, information can flow between layers, modules, and users, and generate programs and/or compute-optimized code to be run on the hardware 130 below. In some embodiments, a user 105 (e.g., scientist, engineer, analyst, domain experts, etc.) can readily develop and interact with low-level (or close-to-the-metal) code via MIP 125 and DSL. In some cases, an output from machine programming may also communicate information (e.g., logs, feedback, etc.) to the user 105.

In some cases, user software, system software and underlying compute substrate may be integrated through MIP layer 125. In some instances, the SI stack may further comprise a hardware abstraction layer. In some examples, the hardware abstraction layer may perform just-in-time (JIT) compilation and integrate MP methods into the compiler, as well as the runtime. In such instances, the Sim-AI OS 115 may provide OS-level performance estimation, dynamic AI-driven CPU/Task allocation, data-driven scheduling, memory management as well as cache policy and networking.

The machine programming or machine intentional programming (MIP) 125 layer described herein may allow for expanding artificial intelligence. Machine programming (MP) may generally comprise automation of software (and hardware). A MIP system as describes herein, may comprise a system that may automate some or all of the operations of turning the user's intent into an executable program and maintaining that program over time. The present MIP implementations may be uniquely suited for the Sim-AI OS and the scientific workflows.

These may be distinct from mainstream ML workflows in ways, such as, significantly affecting data flows, results and/or end-user behaviors. Further, in addition to Sim-AI OS accelerating science and intelligence workflows, MIP can further reduce development time by a degree of automation to reduce the cost of producing secure, correct, and efficient software. These systems can also enable non-programmers to harness the full power of modern computing platforms to solve complex problems correctly and efficiently.

In some embodiments, MP can be reasoned about across three distinct pillars: (i) intention, (ii) invention, and (iii) adaptation. Intention may comprise identifying novel ways and simplifying existing ways for users to express their ideas to a machine. It may also comprise lifting meaning (i.e., semantics) from existing software. Invention may comprise higher-order algorithms and data structures that may fulfill a user's intention. In some cases, inventive systems may simply fuse existing components together to form a novel solution that fulfills the user's intent. Adaptation may comprise taking an invented high-order program and adapting it appropriately to a specific hardware and software ecosystem. This may be done to ensure certain quality characteristics are maintained such as correctness, performance, security, and/or maintainability.

In some embodiments, the hardware layer 130 may be communicably coupled to the MIP layer 125. In some cases, a substrate for compute may comprise commodity hardware (e.g., laptop), using prebuilt libraries (e.g., BLAS), providing one-way interaction upwards. In alternative cases, a substrate for compute may comprise HPC-grade (e.g., 1PF/s CPU, GPU, etc.), which may be bidirectional interaction. In some instances, standard HPC software (e.g., for quantum computing) can be used with the additional injection of Machine Programming (MP) for developing custom new software. In further cases, a substate for compute may comprise specialized hardware (e.g., FPGA, ASIC, or others dynamically reconfigurable hardware, etc.), which can also provide bidirectional interaction. As an example, a simulation model for a CPU may be built and used to create a model, existing compute blocks (functions, instructions) may be selected, and new functions may be defined through MP. In some embodiments, computation may require considerations, including, but not limited to:
Will advances in the motifs lead to new breeds of algorithms that require radically new systems and/or architectures? Can these be implemented as ASICs (Application Specific Integrated Circuits), or will new substrates be desirable?
Will SI inverse design produce novel compute architectures and substrates?
How will the open-endedness paradigm affect computing systems (memory allocation, load balancing, caching, etc.)?
How will Machine Programming influence hardware-software co-design for simulation intelligence (and high-performance computing)?
In addition to the traditional goals of performance and scalability (e.g., latency, throughput, etc.), energy efficiency, and reliability, how will the advancing technologies build abstractions to facilitate reasoning about correctness, security, and privacy?
Will SI-based surrogate modeling enable a landscape shift where computationally lightweight surrogates running on a small number of GPUs replace massive supercomputing workloads (particularly in physical and life sciences simulations)?What will be the metrics and benchmarks to quantify the tradeoffs between such orthogonal computation approaches?

Further, in some embodiments, distributed training algorithms in HPC platforms may be used to benchmark with idealized neural network models and datasets. However, in some cases, benchmarking may not impart insights regarding the actual performance of these approaches in real deployment scenarios. Such cases may include, but may not be limited to when using domain-inspired AI architectures and optimization schemes for data-driven discovery in the context of realistic datasets, which can be noisy, incomplete, and heterogeneous.

Further, physical computation involved in the simulation-AI methods, models, and/or simulations described herein may incorporate optimizing the design of sensors and chips, and learning NNs with physical components. In some embodiments, ML-enabled intelligent sensor design can be used in inverse design and related machine learning techniques to optimally design data acquisition hardware with respect to a user-defined cost function or design constraint. In some cases, such process may comprise:
1. Standard engineering practices produce an initial design αₒ, or a randomized initialization a of parameters and spatial configuration (e.g., in terms of transduction elements or sensing components).
2. Acquisition of raw sensing data Xᵢ, yᵢ from the initial α, and data preprocessing and transformations to Xᵢ′ amenable to machine learning (e.g., normalized, Gaussian noise, etc.).
3. Train a ML model (e.g., NN, GP, etc.) to output sensing results as ŷᵢ.
4. A cost function J(yᵢ, ŷᵢ) is used to evaluate the learned model, using the ground-truth sensing information, yᵢ. In some cases, it may be useful to develop problem-specific cost function with physics-informed constraints (e.g., in multi-physics models).
5. The results from operation ( ) inform a redesign αᵢ+1, which, in some cases can eliminate non-informative or less useful features. In some cases, this operation can also replace such features with adjustments thereof or alternative sensing elements. In some instances, Bayesian optimization (BO) outer-loop can be used to inform the subsequent design, where the learned NN or GP can serve as the surrogate (e.g., in surrogate modeling). In some instances, BO-based NAS methods may also be applied to sensor components and modules.
6. Repeat from operation ( ) for i=0, . . . , N, where termination conditions may be the number of budgeted cycles, convergence on design or outcome, or achieving a down-stream cost function. Depending on the surrogate model choice and optimization scheme, it may be useful to employ transfer learning techniques to reduce the data burden of subsequent iterations.

In some embodiments, such an approach or certain operations in the process described above can improve the overall performance of a sensor and broader data ingestion/modeling system. In some cases, the overall performance may improve with non-intuitive design choices.

As an example, in the field of synthetic biology, a surrogate-based design framework with a neural network trained on RNA sequence-to-function mappings may be designed in order to intelligently design RNA sequences that synthesize and execute a specific molecular sensing task. This can result in an in silico design framework for engineering RNA molecules as programmable response elements to target proteins and small molecules. In such an example, the data-driven approach may outperform prediction accuracy resulting from standard thermodynamic and kinetic modeling. In some cases, data-driven, ML-based sensor designs can outperform “intuitive” designs that may be solely based on analytical/theoretical modeling. In some instances, there can be non-trivial limitations, such as large, well-characterized training datasets to engineer and select sensing features that can statistically separate out various inherent noise terms or artifacts from the target signals of interest. In some further instances, a limitation may comprise the curse of dimensionality, where the high-dimensional space of training data may drown-out the meaningful correlations to the target sensing information.

Automating and optimizing the various processes may also comprise designing, fabricating, and validating computer chips (e.g., ML-based chip design). In some embodiments, ML-based chip design may comprise ML-based “chip floorplanning”, or designing the physical layout of a computer chip. In some cases, this process may comprise placing hypergraphs of circuit components (e.g., macros (memory components) and standard cells (logic gates, e.g., NAND, NOR, XOR, etc.)) onto chip canvases (e.g., two-dimensional grids) so that performance metrics (e.g., power consumption, timing, area, and wire length) can be optimized, while adhering to hard constraints on density and routing congestion. In some embodiments, ML-based chip design may comprise developing a reinforcement learning (RL) approach by framing the task as a sequential Markov decision process (MDP). In some cases, the process may comprise:
States: hypergraph (as an adjacency matrix), node features (width, height, type), edge features (number of connections), current node (macro) to be placed, and metadata of the netlist graph (routing allocations, total number of wires, macros and standard cell clusters).
Actions: all possible locations (grid cells of the chip canvas) onto which the current macro can be placed subject to predefined hard constraints on density or blockages.
Transitions: probability distribution over next states, given a state and an action.
Rewards: always zero but for the last action, where the reward is a negative weighted sum of pro13 wirelength, congestion, and density.

In some cases, graph convolutional NN can be used to learn feature embeddings of the macros and other hypergraph components. In some instances, this architecture may provide advantageous geometric properties for this design space. The benchmark results of this approach can show the generation of chip floorplans that can be comparable or superior to human experts in under six hours, compared to multiple months of manual human effort. This is may allow for AI-driven knowledge expansion, where artificial agents can approach the problem with chip placement experience that may be magnitudes greater in size and diversity than any human expert.

In further embodiments, the process of computer chip development may comprise automation and human-machine teaming. In some cases, this can potentially optimize and accelerate the process, including additional ways simulation-AI can advance chip design. In some instances, the SimNet platform of NN-solvers can be been applied to the problem of design optimization of an FPGA heat sink, which is a multi-physics problem that can be approached with multiple parallel ML surrogates (e.g., with one NN for the flow field and another NN for the temperature field).

### Human-Machine Teaming

As an example illustrated in FIG. 1, the SI stack, the motifs, and applications interact with users of diverse specialties and use-cases. Further, human-machine inference methods described herein (e.g., in simulation-based inference, causal reasoning, etc.) may call for human-in-the-loop processes. Therefore, human-machine teaming (HMT) may comprise mutually beneficial coordination of humans and machine intelligence systems (e.g., AI and ML algorithms and models, various data and information flows, hardware including compute architecture and sensor arrays, etc.). In some embodiments, HMT may overlap with human-computer interaction (HCl). In some cases, HMT may integrate disciplines of computer science, cognitive science, and human-factors engineering in order to design technologies that can enable humans to interact with computers in efficient and novel ways.

In some embodiments, practices in machine learning may comprise developing and optimizing performance of models in isolation rather than seeking richer optimizations that consider human-machine teamwork, let alone considering additional human-in-the-loop challenges affecting model performance (e.g., changes in policies or data distributions, etc.). In some embodiments, HMT includes systems that determine when to consult humans (e.g., when there is low confidence in predictions, informing the human annotator which data to label for active learning, etc.). In some embodiments, HMT may address issues with applicability across domains of science and intelligence, which may include, but are not limited to:
How humans and machines communicate.
How to model the relationship between humans and machines for accomplishing closed feedback loops.
How to quantify and optimize human-machine teamwork.
Machines learning how to best compliment humans.
How human-machine dynamics can influence and evolve the characteristics of errors made by humans and AI models, especially in continual learning contexts.
How to quantify human-machine uncertainties and predict reliability, especially in the context of broader and dynamic systems.
How to provide theoretical guarantees for various HMT subclasses (e.g., online optimization of experiments, active causal discovery, human-machine inference (FIG. 10)), and how to empirically validate them.
How to capture and express the human-machine interactions for a particular application domain (e.g., where do general methods suffice, and where are domain-specific algorithms and interfaces desirable).
Synergistic human-AI systems can be more effective than either alone (e.g., understand this tradeoff precisely, which may vary in metrics and dimensions depending on the domain and use-case).
Laboratory processes and equipment may currently be designed for the traditional, deductive scientific method, where tools assist human scientists and technicians.

Simulation intelligence can provide the opportunity to rethink this human-machine relationship towards new science methods that are inductive, data-driven, and managed by AI (e.g., beyond standard automation).

In some embodiments, the standard HMT approach may be to first train a model m on data x for predicting y, then m may be held fixed when developing the human-interaction components (and broader computational system) and when training a policy q for querying the human. In some cases, in such an approach the introduction of q can cause the x and y distributions to shift, resulting in altered behavior from m that necessitates retraining. In some instances, joint training approaches can mitigate this concern, and can further provide a more optimal teaming workflow. In some examples, this workflow may comprise joint training approaches that consider explicitly the relative strengths of the human and machine. In some examples, a joint discriminative approach may train m while learning q end-to-end from features to decisions, as well as a new decision-theoretic approach to additionally construct probabilistic models for both the AI task and the human response. In such examples, a follow-up operation that calculates the expected value of information for querying the human, and joint training can optimize the utility of the end-to-end system.

In addition to quantifying the value of information in human-machine dynamics, using probabilistic ML methods can also enable the quantification and propagation of uncertainties in HMT. In further embodiments, a class of ML methods for uncertainty estimation in the human-machine coalition setting may comprise evidential learning maps model inputs to the parameters of a Dirichlet distribution over outputs. In such embodiments, smaller parameter values may represent less evidence for a class and thus produce a broader distribution representing greater epistemic uncertainty. Evidential learning can enjoy a direct mapping to subjective logic, a calculus for probabilities expressed with degrees of uncertainty where sources of evidence can have varying degrees of trustworthiness. In some cases, subjective logic may be suitable for modeling and analyzing situations where the available information is relatively incomplete and unreliable, which can be utilized in HMT scenarios for uncertainty-aware logical reasoning. In some further cases, subjective logic may be used for trust calibration, such as in automation bias which can occur when humans readily accept AI or machine outputs, replacing their own thinking or judgement. Conversely, algorithm aversion may occur when humans disregard algorithms for lack of trust, despite the algorithms consistently outperforming humans. In some embodiments, the performance cannot be reliably improved by improving the prediction components in feedback systems powered by ML. In some cases, such an improved prediction system can increase sensitivity to a modeling or data flaw in another part of the engineering pipeline (e.g., human-in-the-loop ML, scientific ML pipelines, etc.).

### Computer Systems

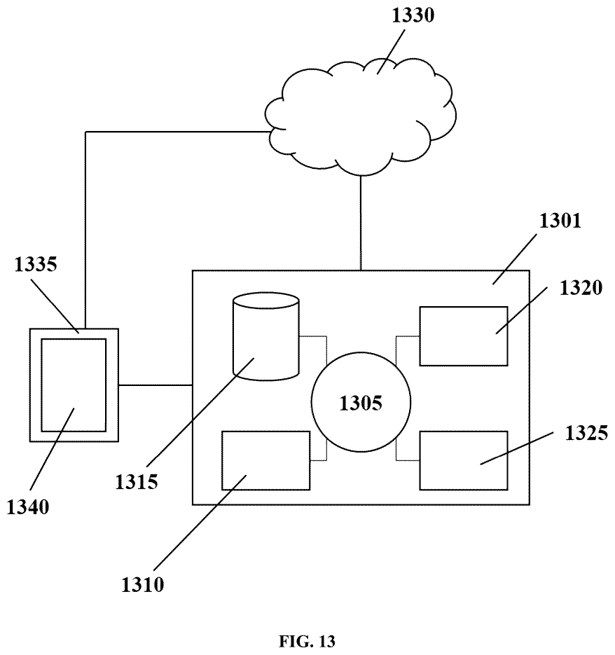

In an aspect, the present disclosure provides computer systems that are programmed or otherwise configured to implement methods of the disclosure, e.g., any of the subject methods for medical imaging. FIG. 13 shows a computer system 1301 that is programmed or otherwise configured to implement a method for (a) providing a simulation module layer that is configured to be integrated and used in a simulation-artificial intelligence (Sim-AI) operating system (OS); and (b) using the one or more domain-specific computing modules for AI-enabled simulations of one or more target applications. The computer system 1301 may be configured to, for example, (i) provide a simulation layer comprising one or more domain-specific computing modules, (ii) receive datasets or data streams by the simulation layer comprising one or more domain-specific computing modules, (iii) use the datasets or data streams and the one or more domain-specific computing modules for AI-enabled simulation, and (iv) generate future predictions based on the AI-enabled simulation. The computer system 1301 can be an electronic device of a user or a computer system that is remotely located with respect to the electronic device. The electronic device can be a mobile electronic device.

The computer system 1301 may include a central processing unit (CPU, also “processor” and “computer processor” herein) 1305, which can be a single core or multi core processor, or a plurality of processors for parallel processing. The computer system 1301 also includes memory or memory location 1310 (e.g., random-access memory, read-only memory, flash memory), electronic storage unit 1315 (e.g., hard disk), communication interface 1320 (e.g., network adapter) for communicating with one or more other systems, and peripheral devices 1325, such as cache, other memory, data storage and/or electronic display adapters. The memory 1310, storage unit 1315, interface 1320 and peripheral devices 1325 are in communication with the CPU 1305 through a communication bus (solid lines), such as a motherboard. The storage unit 1315 can be a data storage unit (or data repository) for storing data. The computer system 1301 can be operatively coupled to a computer network (“network”) 1330 with the aid of the communication interface 1320. The network 1330 can be the Internet, an internet and/or extranet, or an intranet and/or extranet that is in communication with the Internet. The network 1330 in some cases is a telecommunication and/or data network. The network 1330 can include one or more computer servers, which can enable distributed computing, such as cloud computing. The network 1330, in some cases with the aid of the computer system 1301, can implement a peer-to-peer network, which may enable devices coupled to the computer system 1301 to behave as a client or a server.

The CPU 1305 can execute a sequence of machine-readable instructions, which can be embodied in a program or software. The instructions may be stored in a memory location, such as the memory 1310. The instructions can be directed to the CPU 1305, which can subsequently program or otherwise configure the CPU 1305 to implement methods of the present disclosure.

Examples of operations performed by the CPU 1305 can include fetch, decode, execute, and writeback.

The CPU 1305 can be part of a circuit, such as an integrated circuit. One or more other components of the system 1301 can be included in the circuit. In some cases, the circuit is an application specific integrated circuit (ASIC).

The storage unit 1315 can store files, such as drivers, libraries and saved programs. The storage unit 1315 can store user data, e.g., user preferences and user programs. The computer system 1301 in some cases can include one or more additional data storage units that are located external to the computer system 1301 (e.g., on a remote server that is in communication with the computer system 1301 through an intranet or the Internet).

The computer system 1301 can communicate with one or more remote computer systems through the network 1330. For instance, the computer system 1301 can communicate with a remote computer system of a user (e.g., a subject, an end user, a consumer, a healthcare provider, an imaging technician, etc.). Examples of remote computer systems include personal computers (e.g., portable PC), slate or tablet PC's (e.g., Apple® iPad, Samsung® Galal3 Tab), telephones, Smart phones (e.g., Apple® iPhone, Android-enabled device, Blackberry®), or personal digital assistants. The user can access the computer system 1301 via the network 1330.

Methods as described herein can be implemented by way of machine (e.g., computer processor) executable code stored on an electronic storage location of the computer system 1301, such as, for example, on the memory 1310 or electronic storage unit 1315. The machine executable or machine readable code can be provided in the form of software. During use, the code can be executed by the processor 1305. In some cases, the code can be retrieved from the storage unit 1315 and stored on the memory 1310 for ready access by the processor 1305. In some situations, the electronic storage unit 1315 can be precluded, and machine-executable instructions are stored on memory 1310.

The code can be pre-compiled and configured for use with a machine having a processor adapted to execute the code, or can be compiled during runtime. The code can be supplied in a programming language that can be selected to enable the code to execute in a pre-compiled or as-compiled fashion.

Aspects of the systems and methods provided herein, such as the computer system 1301, can be embodied in programming. Various aspects of the technology may be thought of as “products” or “articles of manufacture” in the form of machine (or processor) executable code and/or associated data that is carried on or embodied in a type of machine readable medium.

Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media including, for example, optical or magnetic disks, or any storage devices in any computer(s) or the like, may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a cater wave, or any other medium from which a computer may read programming code and/or data. Many of these forms of computer readable media may be involved in carrying one or more sequences of one or more instructions to a processor for execution.

The computer system 1301 can include or be in communication with an electronic display 1335 that comprises a user interface (UI) 1340 for providing, for example, a portal for interacting with one or more layers of a stack comprising a Sim-AI OS, as described herein. The portal may be provided through an application programming interface (API). A user or entity can also interact with various elements in the portal via the UI. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 1305. For example, the algorithm may be configured to receive datasets or data streams, provide an AI-enabled simulation comprising the datasets or data streams and one or more domain-specific computing modules, generate future predictions based on the AI-enabled simulation, or a combination thereof.

While preferred embodiments of the present disclosure have been shown and described herein, such embodiments are provided by way of example only. It is not intended that the disclosure be limited by the specific examples provided within the specification. While the disclosure has been described with reference to the aforementioned specification, the descriptions and illustrations of the embodiments herein are not meant to be construed in a limiting sense.

Numerous variations, changes, and substitutions will now occur without departing from the disclosure. Furthermore, it shall be understood that all aspects of the disclosure are not limited to the specific depictions, configurations or relative proportions set forth herein which depend upon a variety of conditions and variables. It can be understood that various alternatives to the embodiments of the disclosure described herein may be employed in practicing the disclosure. It is therefore contemplated that the disclosure shall also cover any such alternatives, modifications, variations or equivalents. It is intended that the following claims define the scope of the disclosure and that methods and structures within the scope of these claims and their equivalents be covered thereby.

As used herein, the term “about” in some cases refers to an amount that is approximately the stated amount.

As used herein, the term “about” refers to an amount that is near the stated amount by 10%, 5%, or 1%, including increments therein.

As used herein, the term “about” in reference to a percentage refers to an amount that is greater or less the stated percentage by 10%, 5%, or 1%, including increments therein.

As used herein, the phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

1-20. (canceled)

21. A system comprising:
a simulation module layer that is configured to be integrated and used in a simulation-artificial intelligence (Sim-AI) operating system (OS),
wherein the simulation module layer comprises one or more domain-specific computing modules that are useable for simulation intelligence of one or more target applications.

22. The system of claim 21, wherein the one or more domain-specific computing modules are configured or customized for one or more of the following: simulation-based inference, multi-physics and multi-scale effects, surrogate modeling and emulation, semi-mechanistic modeling, probabilistic domain-specific language (DSL) simulation, open-endedness capabilities, agent-based modeling, or causal machine learning (ML).

23. The system of claim 21, wherein the one or more target applications comprise one or more of the following: parallel computing for interdisciplinary physics, multi-physics multi-scale simulation, simulators as computation graphs for causal reasoning, or uncertainty quantification and reasoning.

24. The system of claim 21, wherein the simulation module layer is provided over one or more programming engines within the Sim-AI OS.

25. The system of claim 24, wherein the one or more programming engines comprise at least one of a probabilistic programming engine or a differentiable programming engine.

26. The system of claim 21, wherein the simulation module layer is configured to be operably coupled to a hardware module layer in a configuration that is optimized for machine code execution.

27. The system of claim 26, wherein the configuration is optimized for machine code execution using at least one or more of the following: (i) domain-specific languages (DSL), (ii) hardware-software design automation, or (iii) machine intentional programming.

28. The system of claim 26, wherein the hardware module layer comprises a flexible hardware system that is operably coupled to a differentiable programming engine, a probabilistic programming engine, or a combination thereof in the Sim-AI OS.

29. The system of claim 26, wherein the hardware module layer comprises a high performance computing (HPC) system that is operably coupled to a probabilistic programming engine, a differentiable programming engine, or a combination thereof in the Sim-AI OS.

30. The system of claim 21, wherein the one or more domain-specific computing modules comprise at least one expert knowledge model that is synergistically combined or fused with at least one data-driven surrogate model.

31. The system of claim 30, wherein the at least one expert knowledge model comprises one or more differential equations, a semi-parametric model, or a non-parametric model.

32. The system of claim 21, wherein the simulation module layer is configured to simulate and learn processes and systems spanning multiple physics processes and/or multiple spatial-temporal scales.

33. The system of claim 21, further comprising encoding domain expertise and causal structure into the simulation module layer.

34. The system of claim 21, wherein the simulation module layer is configured to generate one or more counterfactual simulations that simulate possible future predictions over (i) one or more time scales and (ii) high-dimensional or multimodal data.

35. The system of claim 21, wherein the simulation module layer is capable of being scaled, integrated, compiled, accelerated, or a combination thereof without refactoring or rewriting legacy codebases.

36. The system of claim 21, wherein the simulation module layer, one or more workflow layers, or a combination thereof is configured to receive and integrate real-world datasets and online data streams comprising structured and unstructured data.

37. The system of claim 36, wherein the simulation module layer is configured to be operably coupled to the one or more workflow layers.

38. The system of claim 36, further comprising a user interface (UI) configured to display the one or more workflow layers to a user, wherein the UI is operable by the user to inform development and implementation of the Sim-AI OS.

39. The system of claim 36, wherein the one or more workflow layers comprise at least one of (i) inverse design, (ii) open-ended optimization, (iii) continual learning, (iv) causal inference and discovery, (v) simulator inversion, (vi) human machine interface or active science, (vii) uncertainty reasoning, (viii) counter-factual reasoning, (ix) digital twins with live data, (x) multi-modal simulations, or (xi) physics informed learning.

40. The system of claim 36, further comprising one or more workflow pipelines configured to traverse between two or more of any of (i) the simulation module layer, (ii) the hardware module layer, (iii) the one or more workflow layers, and (iv) information paths between any of (i)-(iii).
